(19) United States
(12) Patent Application Publication
(10) Pub. No.: US 2021/0313804 A1
(43) Pub. Date: Oct. 7, 2021

(54) METHODS AND SYSTEMS FOR ALTERING POWER DURING FLIGHT

(71) Applicant: BETA AIR, LLC, South Burlington, VT (US)

(72) Inventor: Herman Wiegman, Essex Junction, VT (US)

(73) Assignee: BETA AIR, LLC, SOUTH BURLINGTON, VT (US)

(21) Appl. No.: 17/349,372

(22) Filed: Jun. 16, 2021

Related U.S. Application Data
(63) Continuation-in-part of application No. 16/598,307, filed on Oct. 10, 2019.
(60) Provisional application No. 62/896,816, filed on Sep. 6, 2019.

(51) Int. Cl. H02J 1/10; H02J 7/00; G01R 31/3842; G01R 31/371; G01R 31/396; G01R 19/165; B64D 27/24; B64C 29/00; B64D 35/02

(52) U.S. Cl. CPC H02J 1/109; H02J 1/106; H02J 7/0063; H02J 7/0048; G01R 31/3842; G01R 31/371; B64D 2045/007; G01R 19/16542; B64D 27/24; B64C 29/0008; B64D 35/02; B64D 2221/00; G01R 31/396

(57) ABSTRACT

A method of altering propulsor output when powering an electronic aircraft includes calculating a power demand of each propulsor of the plurality of propulsors for at least a future phase of flight, wherein each propulsor is powered by an electrical energy source of a plurality of electrical energy sources. The method includes measuring an electrical parameter of each energy source, calculating a power-production capability of each energy source as a function of the electrical parameter. The method includes identifying at least a compromised energy source of the plurality of energy sources, notifying, by a notification unit, a user of the at least a compromised energy source, and adjusting, as a function of the user notification, the power output from the plurality of energy sources to the plurality of propulsors for a current phase of flight as a function of the power-production capability and the power demand.

### CROSS-REFERENCE TO RELATED APPLICATIONS

This application is a continuation-in-part of U.S. patent application Ser. No. 16/598,307, filed on Oct. 10, 2019, and titled, “METHODS AND SYSTEMS FOR ALTERING POWER DURING FLIGHT” which claims the benefit of priority from U.S. Provisional Patent Application Ser. No. 62/896,816, filed on Sep. 6, 2019, and titled “METHODS AND SYSTEMS FOR OPTIMIZING POWER DURING FLIGHT,” which is incorporated by reference herein in its entirety.

### FIELD OF THE INVENTION

The present invention generally relates to altering the power-production capability of an energy source incorporated into an electrically powered aircraft during flight. In particular, the present invention is directed to methods and systems for altering power during flight.

### BACKGROUND

During flight, an electric aircraft will utilize energy and power from the onboard energy source thus reducing the overall capability of the energy source. Variations in flight plans, paths and phase may contribute to a reduction of the capability of each energy source at an individual rate. Degradation of the capability of the energy source may cause the aircraft to be unable to complete a flight plan or unable to utilize a phase of flight. The negative impacts caused by reduction of the overall capability of the energy source can compromise safety and effective operation of the aircraft. The need for a means of correcting and monitoring the overall capability of the energy source may be met by supervising the power capabilities of the energy source in view of the power demand of the aircraft components.

### SUMMARY OF THE DISCLOSURE

In one aspect, a system for altering propulsor output when powering an electronic aircraft comprises a plurality of energy sources of an electronic aircraft. The system further comprises a plurality of propulsors of an electronic aircraft, wherein the plurality of propulsors are powered by the plurality of energy sources. The system further includes at least a controller in communication with the at least a plurality of energy sources and the at least a plurality of propulsors, wherein the controller is configured to calculate at least a power demand of each propulsor of the plurality of propulsors for at least a future phase of flight. The system further includes a notification unit in communication with the at least a controller. The system further includes at least a sensor in communication with the at least a controller.

In another aspect, a method for altering propulsor output when powering an electronic aircraft by at least a controller, the method comprising calculating, as a function of the at least a plurality of energy sources and at least a plurality of propulsors, at least a power demand of each propulsor of the plurality of propulsors for at least a future phase of flight, wherein each propulsor of the plurality of propulsors is powered by at least an energy source of a plurality of energy sources. The method further comprises measuring at least an electrical parameter of each energy source of the at least a plurality of energy sources. The method further comprises calculating at least a power-production capability of each energy source of the at least a plurality of energy sources as a function of the at least an electrical parameter. The method further includes identifying at least a compromised energy source of the plurality of sources. The method further includes notifying, by a notification unit, a user of the at least a compromised energy source of the plurality of sources. The method further includes adjusting, as a function of the notification to the user by the notification unit, at least a power output from the at least a plurality of energy sources to the at least a plurality of propulsors for at least a current phase of flight as a function of the at least a power-production capability of each energy source of the plurality of energy sources and the at least a power demand of each propulsor of the plurality of propulsors. These and other aspects and features of non-limiting embodiments of the present invention will become apparent to those skilled in the art upon review of the following description of specific non-limiting embodiments of the invention in conjunction with the accompanying drawings.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 is a high-level block diagram depicting an embodiment of a system for altering power during flight;

FIG. 2 is a high-level block diagram depicting an embodiment of plurality of energy sources provided as a module connected to a propulsor;

FIGS. 3A-B are schematic diagrams depicting an embodiment of an aircraft;

FIG. 4 is a block diagram illustrating an exemplary embodiment of a flight controller;

FIG. 5 is a flow diagram illustrating an embodiment of a method for altering power during a phase of flight;

FIG. 6 is a graph illustrating an embodiment of open circuit voltage and derivative with respect to state of charge of open circuit voltage, plotted against state of charge;

FIGS. 7A-B are graphs illustrating embodiments of lines of hover time plotted on a chart of terminal voltage versus load current;

FIG. 8A-B are graphs showing a state of charge of an energy source as a function of time in an embodiment;

FIG. 9 is a block diagram illustrating an exemplary embodiment of a machine learning module; and

FIG. 10 is a block diagram of a computing system that can be used to implement any one or more of the methodologies disclosed herein and any one or more portions thereof.

The drawings are not necessarily to scale and may be illustrated by phantom lines, diagrammatic representations and fragmentary views. In certain instances, details that are not necessary for an understanding of the embodiments or that render other details difficult to perceive may have been omitted.

### DETAILED DESCRIPTION

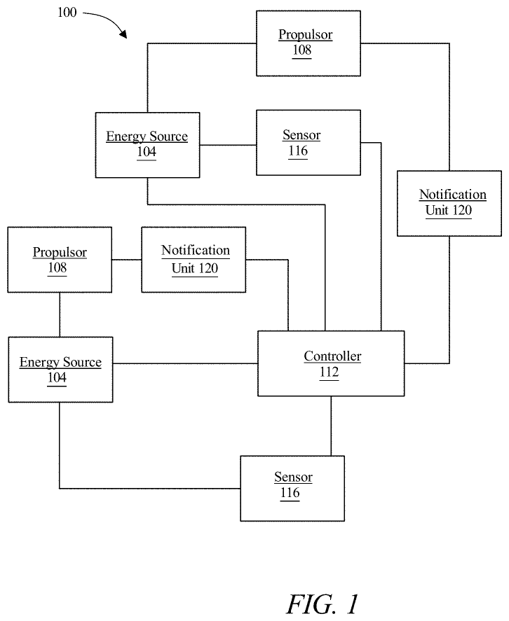

In the following description, for the purposes of explanation, numerous specific details are set forth in order to provide a thorough understanding of the present invention. It will be apparent, however, that the present invention may be practiced without these specific details. As used herein, the word “exemplary” or “illustrative” means “serving as an example, instance, or illustration.” Any implementation described herein as “exemplary” or “illustrative” is not necessarily to be construed as preferred or advantageous over other implementations. All of the implementations described below are exemplary implementations provided to enable persons skilled in the art to make or use the embodiments of the disclosure and are not intended to limit the scope of the disclosure, which is defined by the claims. For purposes of description herein, the terms “upper”, “lower”, “left”, “rear”, “right”, “front”, “vertical”, “horizontal”, and derivatives thereof shall relate to the invention as oriented in FIG. 1. Furthermore, there is no intention to be bound by any expressed or implied theory presented in the preceding technical field, background, brief summary or the following detailed description. It is also to be understood that the specific devices and processes illustrated in the attached drawings, and described in the following specification, are simply exemplary embodiments of the inventive concepts defined in the appended claims. Hence, specific dimensions and other physical characteristics relating to the embodiments disclosed herein are not to be considered as limiting, unless the claims expressly state otherwise.

At a high level, aspects of the present disclosure are directed to systems and methods for altering propulsor output when powering an electronic aircraft. Systems for altering propulsor output when powering an electronic aircraft may be integrated into any electronic aircraft and/or any vertical takeoff and landing aircraft. Embodiments of the systems and methods disclosed herein describe altering the power output for an electric aircraft by a novel process of identifying an energy source with reduced power output and altering the allocation of the remaining energy from the energy sources providing power to the propulsors during a phase of flight. This novel system may result in all energy sources able to perform at high capability during a later phase of flight, such as landing, in which reduction of power to propulsors would be more problematic. In an embodiment, the power-production capability of an energy source is determined by measuring at least an electrical parameter with a sensor communicatively connected to energy source and potential power output is determined, which is compared with the energy required to maneuver during a particular phase of flight and the remaining portions of flight. Embodiments may include methods for reducing the power output directed to the propulsors or other power demanding functions to compensate for reduced power output of an energy source during a phase of flight in addition to modifying the flight and flight plan to maintain power levels during the remaining portions of flight.

Referring now to the drawings, FIG. 1 illustrates an embodiment of a system 100 for altering propulsor power output when powering an electronic aircraft. System 100 may be incorporated in an electric aircraft or other electrically powered vehicle, for instance as described below. System 100 may be further incorporated into a vertical takeoff and landing aircraft, for instance as described below. System 100 includes a plurality of energy sources 104. An energy source, of plurality of energy sources 104 may include at least a cell, such as a chemoelectrical, photo electric, or fuel cell, as described in further detail below. An energy source of a plurality of energy sources 104 may include, without limitation, a generator, a photovoltaic device, a fuel cell such as a hydrogen fuel cell, direct methanol fuel cell, and/or solid oxide fuel cell, or an electric energy storage device; electric energy storage device may include without limitation a capacitor, an inductor, an energy storage cell and/or a battery. An energy source of plurality of energy sources 104 may include a battery cell or a plurality of battery cells connected in series into a module; each module may be connected in series or in parallel with other modules. Configuration of an energy source containing connected modules may be designed to meet an energy or power requirement and may be designed to fit within a designated footprint in an electric aircraft in which system 100 may be incorporated. At least an energy source of plurality of energy sources 104 may be used to provide a steady supply of electrical power to a load over the course of a flight by a vehicle or other electric aircraft; the at least an energy source may be capable of providing sufficient power for “cruising” and other relatively low-energy phases of flight. An energy source of plurality of energy sources 104 may be capable of providing electrical power for some higher-power phases of flight as well. An energy source of plurality of energy sources 104 may be capable of providing sufficient electrical power for auxiliary loads, including without limitation lighting, navigation, communications, de-icing, steering or other systems requiring power or energy. An energy source of plurality of energy sources 104 may be capable of providing sufficient power for controlled descent and landing protocols, including without limitation hovering descent or runway landing. At least an energy source 104, of a plurality of energy sources, may include a device for which power that may be produced per unit of volume and/or mass has been optimized, at the expense of the maximal total specific energy density or power capability, during design.

Still referring to FIG. 1, non-limiting examples of items that may be used as at least an energy source 104 may include batteries used for starting applications including Li ion batteries which may include NCA, NMC, Lithium iron phosphate (LiFePO4) and Lithium Manganese Oxide (LMO) batteries, which may be mixed with another cathode chemistry to provide more specific power if the application requires Li metal batteries, which have a lithium metal anode that provides high power on demand, Li ion batteries that have a silicon, tin nanocrystals, graphite, graphene or titanite anode, or the like. Batteries may include without limitation batteries using nickel-based chemistries such as nickel cadmium or nickel metal hydride, batteries using lithium ion battery chemistries such as a nickel cobalt aluminum (NCA), nickel manganese cobalt (NMC), lithium iron phosphate (LiFePO4), lithium cobalt oxide (LCO), and/or lithium manganese oxide (LMO), batteries using lithium polymer technology, metal-air batteries. At least an energy source of plurality of energy sources 104 may include lead-based batteries such as without limitation lead acid batteries and lead carbon batteries. An energy source of plurality of energy sources 104 may include lithium sulfur batteries, magnesium ion batteries, and/or sodium ion batteries. Batteries may include solid state batteries or supercapacitors or another suitable energy source. Batteries may be primary or secondary or a combination of both. Persons skilled in the art, upon reviewing the entirety of this disclosure, will be aware of various devices of components that may be used as at least energy source of plurality of energy sources 104. An energy source of plurality of energy sources 104 may be used, in an embodiment, to provide electrical power to an electric aircraft or drone, such as an electric aircraft vehicle, during moments requiring high rates of power output, including without limitation takeoff, landing, thermal de-icing and situations requiring greater power output for reasons of stability, such as high turbulence situations, as described in further detail below.

Still referring to FIG. 1, at least an energy source of plurality of energy sources 104 may supply power to perform a plurality of critical functions in an aircraft incorporating system 100. Critical functions in an aircraft may include, without limitation, communications, anti-collision, lighting, navigation, de-icing, steering cruising, taxiing, take off, landing and descents. High peak loads may be necessary to perform certain take off protocols which include vertical takeoff or runway takeoff, or landing protocols which may include, but are not limited to, hovering descents, runway descents, or a combination of both. During takeoff and landing, propulsors 108 may demand a higher power level than cruising as required to ascend or descend in a controlled manner. When at least an energy source 104 of a plurality of energy sources, is at high state of charge, it may be capable of supporting a peak load during high power demands and continued in-flight cruising functions. As an energy source of plurality of energy sources 104 approaches a low state of charge and/or descends toward a minimum allowable voltage, as a result of supporting operations in flight, energy source may not be capable of supporting peak loads of one or more mission critical functions. An energy source of plurality of energy sources 104 may become substantially discharged during any in-flight function due to in-flight power consumption and unforeseen power and current draws that may occur during flight; the power and current draws may be imposed by environmental conditions, components of the energy source or other factors which impact the energy source state of charge (SOC) and/or ability to supply power. The components of an energy source of plurality of energy sources 104 may be faulty or compromised due to manufacturing or to wear out which may impact negatively, the SOC and/or ability to supply power of the energy source. SOC, as used herein, is a measure of remaining capability as a function of time and is described in more detail below. SOC and/or the maximum power at least an energy source of plurality of energy sources 104 is capable of delivering may decrease during flight as the voltage decreases during discharge. At least an energy source of plurality of energy sources 104 may be able to support landing according to a given landing protocol during a partial state of charge (PSOC) or at a lower voltage, but this ability may depend on demands required for the landing protocol. Demands required for the landing protocol may include, without limitation, environmental inputs, weather inputs or air traffic at the time of landing. Vehicle or aircraft landing power needs may exceed measured power consumption at any particular time in flight. An energy source of plurality of energy sources 104 may become degraded during the lifetime of in used charge and discharge which may reduce power output and performance. An energy source of plurality of energy sources 104 may be degraded due to mechanical issues or defects which arise during the operations under load or during stand which will cause a reduced power level. An energy source of plurality of energy sources 104 may be further degraded due to load imbalances during flight, which can drain and energy source 104 prematurely.

Continuing to refer to FIG. 1 each energy source of plurality of energy sources 104 may be connected to a propulsor 108 of a plurality of propulsors. Propulsor 108 may be any device or component that consumes electrical power on demand to propel an electric aircraft or other vehicle while on ground or in flight. Propulsor 108 may include one or more propulsive devices. At least a propulsive device may include any device or component that converts the mechanical energy of a motor, for instance in the form of rotational motion of a shaft, into thrust in a fluid medium. At least a propulsive device may include, without limitation, a device using moving or rotating foils, including without limitation one or more rotors, an airscrew or propeller, a set of airscrews or propellers such as contra-rotating propellers, a moving or flapping wing, or the like. At least a propulsive device may include without limitation a marine propeller or screw, an impeller, a turbine, a pump-jet, a paddle or paddle-based device, or the like. As another non-limiting example, at least a propulsive device may include an eight-bladed pusher propeller, such as an eight-bladed propeller mounted behind the engine to ensure the drive shaft is in compression. Persons skilled in the art, upon reviewing the entirety of this disclosure, will be aware of various devices that may be used as at least a propulsor 108. At least an energy source 104, of a plurality of energy sources, may supply power to at least a propulsor 108. Propulsor 108 may convert electrical energy into kinetic energy; for instance, propulsor 108 may include one or more electric motors.

Still viewing FIG. 1, one or more energy sources of plurality of energy sources 104 may be connected to an additional load. Additional load may convert electrical energy into heat; additional load may include resistive loads. Additional load may convert electrical energy into light. Additional load may include one or more elements of digital or analog circuitry; for instance, additional load may consume power in the form of voltage sources to provide a digital circuit's high and low voltage threshold levels, to enable amplification by providing “rail” voltages, or the like. Additional load may include, as a non-limiting example, control circuits and/or controllers as described in further detail below, including any flight controller as described herein. At least an energy source 104, of a plurality of energy sources, may connect to additional load using an electrical connection enabling electrical or electromagnetic power transmission, including any conductive path from at least an energy source 104, of a plurality of energy sources to additional load any inductive, optical or other power coupling such as an isolated power coupling, or any other device or connection usable to convey electrical energy from an electrical power, voltage, or current source.

Continuing to refer to FIG. 1, system 100 may include a controller 112. Controller 112 may include and/or communicate with any computing device as described in this disclosure, including without limitation a microcontroller, microprocessor, digital signal processor (DSP) and/or system on a chip (SoC) as described in this disclosure. Controller 112 may be installed in an aircraft, may control the aircraft remotely, and/or may include an element installed in the aircraft and a remote element in communication therewith. Controller 112 may be similar to or the same as flight controller 404 as described hereinbelow. Controller 112 may include, be included in, and/or communicate with a mobile device such as a mobile telephone or smartphone. Controller 112 may include a single computing device operating independently, or may include two or more computing device operating in concert, in parallel, sequentially or the like; two or more computing devices may be included together in a single computing device or in two or more computing devices. Controller 112 with one or more additional devices as described below in further detail via a network interface device. Network interface device may be utilized for connecting a controller 112 to one or more of a variety of networks, and one or more devices. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network may employ a wired and/or a wireless mode of communication. In general, any network topology may be used. Information (e.g., data, software etc.) may be communicated to and/or from a computer and/or a computing device. Controller 112 may include but is not limited to, for example, a controller 112 or cluster of computing devices in a first location and a second computing device or cluster of computing devices in a second location. Controller 112 may include one or more computing devices dedicated to data storage, security, distribution of traffic for load balancing, and the like. Controller 112 may distribute one or more computing tasks as described below across a plurality of computing devices of computing device, which may operate in parallel, in series, redundantly, or in any other manner used for distribution of tasks or memory between computing devices. Controller 112 may be implemented using a “shared nothing” architecture in which data is cached at the worker, in an embodiment, this may enable scalability of system 100 and/or computing device.

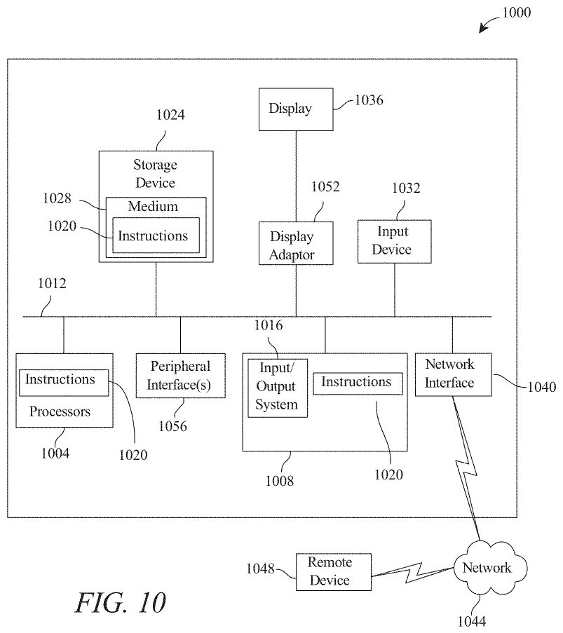

Still referring to FIG. 1, at least a controller 112 is in communication with the at least an energy source 104 of a plurality of energy sources and the at least a propulsor 108 of the plurality of propulsors. At least a controller 112 may be communicatively connected to the at least an energy source 104 of a plurality of energy sources and the at least a propulsor 108 of the plurality of propulsors. As used herein, “communicatively connecting” is a process whereby one device, component, or circuit is able to receive data from and/or transmit data to another device, component, or circuit; communicative connection may be performed by wired or wireless electronic communication, either directly or by way of one or more intervening devices or components. In an embodiment, communicative connecting includes electrically coupling at least an output of one device, component, or circuit to at least an input of another device, component, or circuit. Communicative connecting may be performed via a bus or other facility for intercommunication between elements of a computing device as described in further detail below in reference to FIG. 10. Communicative connecting may include indirect connections via “wireless” connection, radio communication, low power wide area network, optical communication, magnetic, capacitive, or optical coupling, or the like. Controller 112 may include any computing device or combination of computing devices as described in detail below in reference to FIG. 10. Controller 112 may include any processor or combination of processors as described below in reference to FIG. 10. Controller 112 may include a microcontroller. Controller 112 may be incorporated in the electric aircraft or may be in remote contact.

Still referring to FIG. 1, controller 112 may be communicatively connected, as defined above, to each propulsor 108 of plurality of propulsors; as used herein, controller 112 is communicatively connected to each propulsor where controller 112 is able to transmit signals to each propulsor and each propulsor is configured to modify an aspect of propulsor behavior in response to the signals. As a non-limiting example, controller 112 may transmit signals to propulsor 108, of plurality of propulsors, via an electrical circuit connecting controller 112 to the propulsor 108, of a plurality of propulsors; the circuit may include a direct conductive path from controller 112 to propulsor or may include an isolated coupling such as an optical or inductive coupling. Alternatively or additionally, controller 112 may communicate with propulsor 108, of a plurality of propulsors, using wireless communication, such as without limitation communication performed using electromagnetic radiation including optical and/or radio communication, or communication via magnetic or capacitive coupling. Persons skilled in the art will be aware, after reviewing the entirety of this disclosure, of many different forms and protocols of communication that may be used to communicatively couple controller 112 to a propulsor 108 of plurality of propulsors.

In an embodiment and still referring to FIG. 1, controller 112 may include a reconfigurable hardware platform. A “reconfigurable hardware platform,” as used herein, is a component and/or unit of hardware that may be reprogrammed, such that, for instance, a data path between elements such as logic gates or other digital circuit elements may be modified to change an algorithm, state, logical sequence, or the like of the component and/or unit. This may be accomplished with such flexible high-speed computing fabrics as field-programmable gate arrays (FPGAs), which may include a grid of interconnected logic gates, connections between which may be severed and/or restored to program in modified logic. Reconfigurable hardware platform may be reconfigured to enact any algorithm and/or algorithm selection process received from another computing device and/or created using machine-learning and/or neural net processes as described below.

Still referring to FIG. 1, system 100 may include at least a sensor 116 configured to detect at least an electrical parameter. At least a sensor 116 may be communicatively connected to controller 112. Sensors, as described herein, are any device, module, and/or subsystems, utilizing any hardware, software, and/or any combination thereof to detect events and/or changes in the instant environment and communicate the information to the at least a controller. At least a sensor may include at least a sensor configured to detect the at least an electrical parameter. At least a sensor 116 may include at least an environmental sensor. As used herein, at least an environmental sensor may be used to detect ambient temperature, barometric pressure, air velocity, motion sensors which may include gyroscopes, accelerometers, inertial measurement unit (IMU), various magnetic, humidity, oxygen. At least a sensor 116 may include at least a geospatial sensor. As used herein, a geospatial sensor may include optical/radar/Lidar, GPS and may be used to detect aircraft location, aircraft speed, aircraft altitude and whether the aircraft is on the correct location of the flight plan. At least a sensor 116 may be located inside the electric aircraft; at least a sensor may be inside a component of the aircraft. In an embodiment, environmental sensor may sense one or more environmental conditions or parameters outside the electric aircraft, inside the electric aircraft, or within or at any component thereof, including without limitation at least an energy source 104, at least a propulsor, or the like. At least a sensor 116 may be incorporated into vehicle or aircraft or be remote. At least a sensor 116 may be communicatively connected to the controller 112.

Still referring to FIG. 1, controller 112 may use a sensor of at least a sensor 116 to determine at least an electrical parameter of at least an energy source 104. At least an electrical parameter may include, without limitation, voltage, current, impedance, resistance, and/or temperature. Current may be measured by using a sense resistor in series with the circuit and measuring the voltage drop across the resister, or any other suitable instrumentation and/or methods for detection and/or measurement of current. Voltage may be measured using any suitable instrumentation or method for measurement of voltage, including methods for estimation as described in further detail below. Each of resistance, current, and voltage may alternatively or additionally be calculated using one or more relations between impedance and/or resistance, voltage, and current, for instantaneous, steady-state, variable, periodic, or other functions of voltage, current, resistance, and/or impedance, including without limitation Ohm's law and various other functions relating impedance, resistance, voltage, and current with regard to capacitance, inductance, and other circuit properties. Alternatively, or additionally, controller 112 may be wired to at least an energy source 104 via, for instance, a wired electrical connection. Controller 112 may measure voltage, current, or other electrical connection. This may be accomplished, for instance, using an analog-to-digital converter, one or more comparators, or any other components usable to measure electrical parameters using an electrical connection that may occur to any person skilled in the art upon reviewing the entirety of this disclosure. Sensor 116 may be used to measure a plurality of electrical parameters. In an embodiment, and as a non-limiting example, a first electrical parameter may include, without limitation, voltage, current, resistance, or any other parameter of an electrical system or circuit; a second electrical parameter may be a function of the first electrical parameter. A third electrical parameter may be calculated from the first and second electrical parameters as a delta or function. For example, current may be calculated from the voltage measurement. Resistance may be calculated from using the voltage and current measurements.

In an embodiment, controller 112 may designed and configured to measure at least an electrical parameter of each energy source 104 of the plurality of energy sources, as an example and without limitation. As a further non-limiting example, controller 112 may be configured to determine as a function of the at least an electrical parameter power-production capability of the at least an electrical energy source. As another example and without limitation, controller 112 may be further configured to calculate at least a projected energy need of electric aircraft, as a function of a flight plan for the electric aircraft. As a non-limiting example, controller 112 may be further designed and configured to determine whether the power-production capability is sufficient for the projected energy need.

With continued reference to FIG. 1, in an embodiment where system 100 is incorporated into an electric aircraft, controller 112 may be programmed to operate electronic aircraft to perform at least a flight maneuver; at least a flight maneuver may include taxiing, takeoff, landing, stability control maneuvers, emergency response maneuvers, regulation of altitude, roll, pitch, yaw, speed, acceleration, or the like during any phase of flight. At least a flight maneuver may include a flight plan or sequence of maneuvers to be performed during a flight plan. At least a flight maneuver may include a runway landing, defined herein as a landing in which a fixed-wing aircraft, or other aircraft that generates lift by moving a foil forward through air, flies forward toward a flat area of ground or water, alighting on the flat area and then moving forward until momentum is exhausted on wheels or (in the case of landing on water) pontoons; momentum may be exhausted more rapidly by reverse thrust using propulsors, mechanical braking, electric braking, or the like. At least a flight maneuver may include a vertical landing protocol, which may include a rotor-based landing such as one performed by rotorcraft such as helicopters or the like. In an embodiment, vertical takeoff and landing protocols may require greater expenditure of energy than runway-based landings; the former may, for instance, require substantial expenditure of energy to maintain a hover or near-hover while descending or ascending, while the latter may require a net decrease in energy to approach or achieve aerodynamic stall. Controller 112 may be designed and configured to operate electronic aircraft via fly-by-wire. At least a flight maneuver may include a runway takeoff, defined herein as a takeoff in which a fixed-wing aircraft, or other aircraft, accelerates on a runway to a particular speed at which time the elevators on the tail will be forced down by backpressure which will raise the nose of the aircraft generating lift.

With continued reference to FIG. 1, controller 112 may direct loads, which may include first propulsor 108, to perform one or more flight maneuvers as described above, including taxiing, takeoff, cruising, landing, and the like. Controller 112 may be configured to perform a partially or fully automated flight plan. In an embodiment, controller 112 may be configured to command first propulsor 108, such as one or more motors or propellers, to increase power consumption, for instance to transition to rotor-based flight at aerodynamic stall during a vertical landing procedure or to a runway based controlled descent. Controller 112 may determine a moment to send a command to an instrument to measure time, such as a clock, by receiving a signal from one or more sensors, or a combination thereof; for instance, controller 112 may determine by reference to a clock and/or navigational systems and sensors that electric aircraft is approaching a destination point, reduce airspeed to approach aerodynamic stall, and may generate a timing-based prediction for the moment of aerodynamic stall to compare to a timer, while also sensing a velocity or other factor consistent with aerodynamic stall before issuing the command. Persons skilled in the art will be aware, upon reviewing the entirety of this disclosure, of various combinations of sensor inputs and programming inputs that controller 112 may use to guide, modify, or initiate flight maneuvers including landing, steering, adjustment of route, and the like.

Referring still to FIG. 1, controller 112 may be designed and configured to perform any method or method steps, or sequence of method steps in any embodiment as described in further detail in this disclosure, in any order and with any degree of repetition, including without limitation by any form of configuration or programming described below. In a non-limiting example, controller 112 may be designed and configured to calculate a power demand of each propulsor of plurality of propulsors for at least a future phase of flight, measure at least an electrical parameter of each electrical energy source of the plurality of energy sources calculate a power-production capability of each energy source of the plurality of energy sources as a function of the at least an electrical parameter identify at least a compromised energy source of the plurality of sources which does not meet the threshold power capability for the required power demand and adjust power output from the plurality of energy sources to the plurality of propulsors for a current phase of flight to compensate for the at least a compromised energy source which does not have adequate power capability.

Still referring to FIG. 1, identifying at least a compromised energy source of the plurality of sources further includes identifying which compromised energy source 104 does not meet the threshold power capability for the required power demand. As a further non-limiting example, the power capability of each energy source 104 of the plurality of energy sources may be determined, or aggregated, and the result compared to a threshold power capability. The threshold power capability of each energy source of the plurality of energy sources 104, for example and without limitation, may be the required power to continue to function properly. As another example and without limitation, the threshold power capability of each energy source 104 of the plurality of energy sources 104 may be the required power to complete the schedule flight plan and/or path. As a further example and without limitation, the threshold power capability may be the required power capability of each energy source of the plurality of energy sources 104 to complete the required phase of flight, such as fixed-wing flight and/or rotor-based flight. Persons skilled in the art, upon reviewing the entirety of this disclosure, will be aware of various embodiments that may be used as the threshold power capability of each energy source 104 of the plurality of energy sources.

With continued reference to FIG. 1, controller 112 may be configured to perform a single step or sequence repeatedly until a desired or commanded outcome is achieved; repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. Controller 112 may perform any step or sequence of steps as described in this disclosure in parallel, such as simultaneously and/or substantially simultaneously performing a step two or more times using two or more parallel threads, processor cores, or the like; division of tasks between parallel threads and/or processes may be performed according to any protocol suitable for division of tasks between iterations. Persons skilled in the art, upon reviewing the entirety of this disclosure, will be aware of various ways in which steps, sequences of steps, processing tasks, and/or data may be subdivided, shared, or otherwise dealt with using iteration, recursion, and/or parallel processing.

With continued reference to FIG. 1, system 100 includes notification unit 120. Notification unit 120 may include a graphical user interface (GUI). For the purposes of this disclosure, a “graphical user interface” is a device configured to present data or information in a visual manner to a user, computer, camera or combination thereof. Notification unit 120 may be configured to display information regarding energy source 104. Notification unit 120 may be configured to display information regarding a compromised energy source 104 such as during a certain state of charge, when a threshold charge value is reached or approached, electrical parameters associated with the function of energy source 104, capability of the compromised energy source 104, or the like. Notification unit 120 may prompt a user for an interaction. Notification unit 120 may be configured to receive haptic, audio, visual, gesture, passkey, or other type of interaction from a user. Notification unit 120 may perform one or more functions in response to the interaction from a user. In non-limiting examples, and without limitation, notification unit 120 may transmit a signal to controller 112 when an affirmative interaction is received from the user, the signal indicating to transmit one or more signals to other components communicatively connected thereto, such as propulsor 108. Notification unit 120 may operate completely outside the communication between controller 112 and any other component communicatively connected thereto. For example and without limitation, notification unit 120 may indicate to the user that energy source 104 has a certain level of charge and system 100 may operate autonomously to adjust one or more electrical commands regardless of the notification to the user.

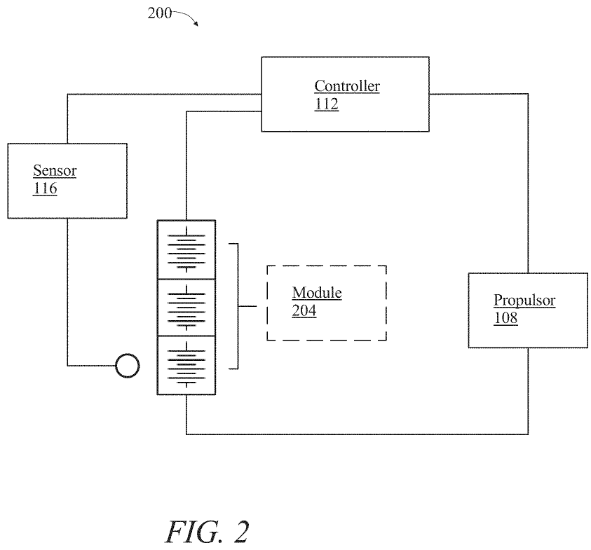

Referring now to FIG. 2, at least an energy source of plurality of energy sources 104 may include a battery cell or a plurality of battery cells making a battery module 204. Module 204 may include batteries connected in parallel or in series or a plurality of modules connected either in series or in parallel designed to deliver both the power and energy requirements of the application or a phase of the operation. Connecting batteries in series may increase the voltage of an energy source of plurality of energy sources 104, which may provide more power on demand. High voltage batteries may require cell matching when high peak load is provided. As more cells are connected in strings there may exist the possibility of one cell failing which may increase resistance in the module and reduce the overall power output as the voltage of the module may decrease as a result of that failing cell. Connecting batteries in parallel may increase total current capability by decreasing total resistance, and also may increase overall amp-hour capability which increases the energy output of a battery. The overall energy and power outputs of an energy source of plurality of energy sources 104 may be based on the individual battery cell performance or an extrapolation based on the measurement of at least an electrical parameter. In an embodiment where an energy source of plurality of energy sources 104 includes a plurality of cells, such as battery cells, overall power output capability may be dependent on electrical parameters of each individual cell of plurality of cells. At least an energy source of plurality of energy sources 104 may further include, without limitation, wiring, conduit, housing, cooling systems, heating systems, sensors, hold down mechanisms, insulation and battery management systems. Persons skilled in the art will be aware, after reviewing the entirety of this disclosure, of many different potential components of a plurality of energy sources in energy source 104, of a plurality of energy sources.

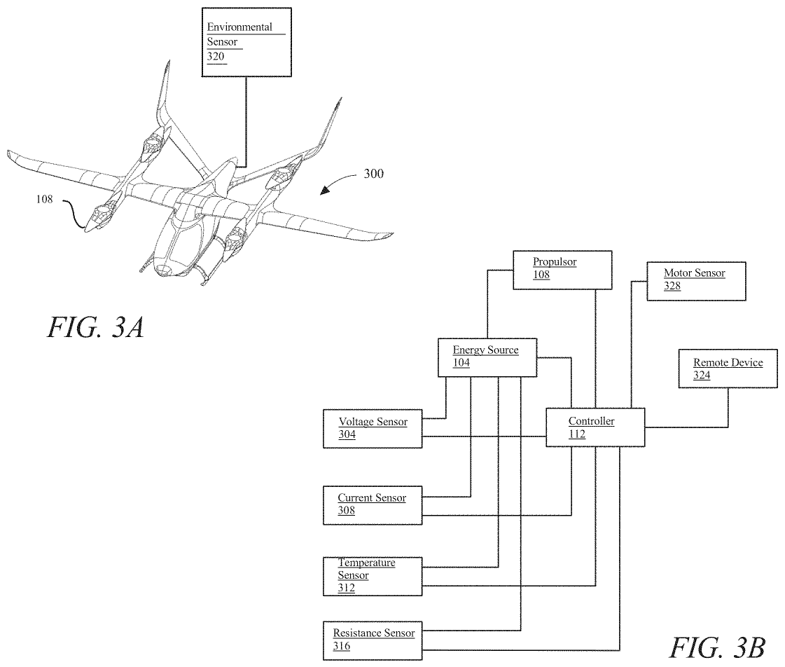

Referring to FIG. 3A and FIG. 3B, system 100 may be incorporated in an electronic aircraft 300. Electronic aircraft 300 may be an electric vertical takeoff and landing (eVTOL) aircraft. An electronic aircraft may be an aircraft powered by at least an energy source 104, of a plurality of energy sources. Electronic aircraft 300 may include one or more wings or foils for fixed-wing or airplane-style flight and/or one or more rotors for rotor-based flight. Electronic aircraft 300 may include an aircraft controller 136 communicatively and/or operatively connected to each wing, or foil, and/or each rotor. Electronic aircraft 300 may be capable of rotor-based cruising flight, rotor-based takeoff, rotor-based landing, fixed-wing cruising flight, airplane-style takeoff, airplane-style landing, and/or any combination thereof. Rotor-based flight, as described herein, is where the aircraft generated lift and propulsion by way of one or more powered rotors coupled with an engine, such as a “quad copter,” multi-rotor helicopter, or other vehicle that maintains its lift primarily using downward thrusting propulsors. Fixed-wing flight, as described herein, is where the aircraft is capable of flight using wings and/or foils that generate life caused by the aircraft's forward airspeed and the shape of the wings and/or foils, such as airplane-style flight.

With continued reference to FIG. 3A-B, a number of aerodynamic forces may act upon the electronic aircraft 300 during flight. Forces acting on an electronic aircraft 300 during flight may include thrust, the forward force produced by the rotating element of the electronic aircraft 300 and acts parallel to the longitudinal axis. Drag may be defined as a rearward retarding force which is caused by disruption of airflow by any protruding surface of the electronic aircraft 300 such as, without limitation, the wing, rotor, and fuselage. Drag may oppose thrust and acts rearward parallel to the relative wind. Another force acting on electronic aircraft 300 may include weight, which may include a combined load of the electronic aircraft 300 itself, crew, baggage and fuel. Weight may pull electronic aircraft 300 downward due to the force of gravity. An additional force acting on electronic aircraft 300 may include lift, which may act to oppose the downward force of weight and may be produced by the dynamic effect of air acting on the airfoil and/or downward thrust from at least a propulsor 108. Lift generated by the airfoil may depends on speed of airflow, density of air, total area of an airfoil and/or segment thereof, and/or an angle of attack between air and the airfoil.

Continuing to refer to FIGS. 3A-B a plurality of sensors may be incorporated in system 100 and/or electronic aircraft 300. Sensors of plurality of sensors may be designed to measure a plurality of electrical parameters or environmental data in-flight, for instance as described above. Plurality of sensors may, as a non-limiting example, include a voltage sensor 304, wherein voltage sensor 304 is designed and configured to measure the voltage of the at least an energy source 104. As a further-non-limiting example, the plurality of sensors may include a current sensor 308, wherein current sensor 308 is designed and configured to measure the current of the at least an energy source 104. As a further non-limiting example, the plurality of sensors may include a temperature sensor 312, wherein temperature sensor 312 is designed and configured to measure the temperature of at least an energy source 104. As a further non-limiting example, a plurality of sensors may include a resistance sensor 316, wherein resistance sensor 316 is designed and configured to measure the resistance of at least an energy source 104. As another non-limiting example, a plurality of sensors may include at least an environmental sensor 320, wherein environmental sensor 320 may be designed and configured to measure a plurality of environmental data including, without limitation, ambient air temperature, barometric pressure, turbulence, and the like. Environmental sensor 320 may be designed and configured, without limitation, to measure geospatial data to determine the location and altitude of the electronically powered aircraft by any location method including, without limitation, GPS, optical, satellite, lidar, radar. Environmental sensor 320, as an example and without limitation, may be designed and configured to measure at a least a parameter of the motor. Environmental sensor 320 may be designed and configured, without limitation, to measure at a least a parameter of the propulsor. Sensor datum collected in flight, by sensors as described herein, may be transmitted to the controller 112 or to at least a remote device 324, which may be any device as described herein and may be used to calculate the power output capability of at least an energy source 104 and/or projected energy needs of electric aircraft during flight, as described in further detail below.

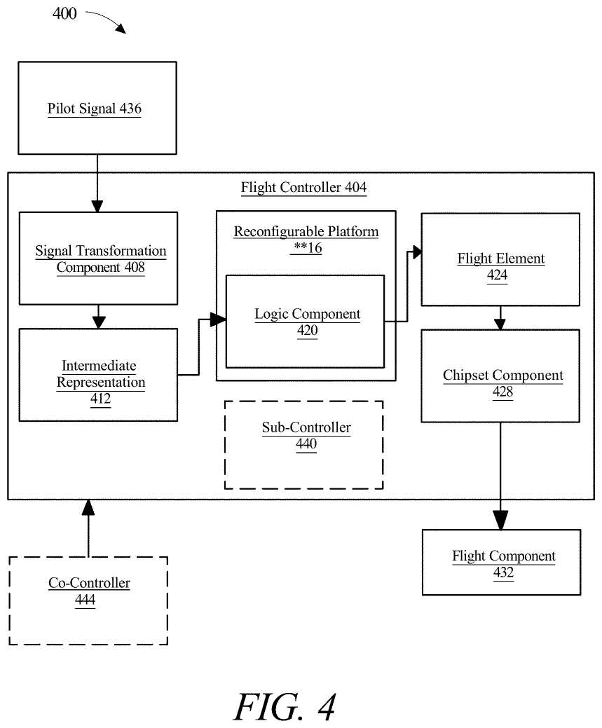

Now referring to FIG. 4, an exemplary embodiment 400 of a flight controller 404 is illustrated. As used in this disclosure a “flight controller” is a computing device of a plurality of computing devices dedicated to data storage, security, distribution of traffic for load balancing, and flight instruction. Flight controller 404 may include and/or communicate with any computing device as described in this disclosure, including without limitation a microcontroller, microprocessor, digital signal processor (DSP) and/or system on a chip (SoC) as described in this disclosure. Further, flight controller 404 may include a single computing device operating independently, or may include two or more computing device operating in concert, in parallel, sequentially or the like; two or more computing devices may be included together in a single computing device or in two or more computing devices. In embodiments, flight controller 404 may be installed in an aircraft, may control the aircraft remotely, and/or may include an element installed in the aircraft and a remote element in communication therewith.

In an embodiment, and still referring to FIG. 4, flight controller 404 may include a signal transformation component 408. As used in this disclosure a “signal transformation component” is a component that transforms and/or converts a first signal to a second signal, wherein a signal may include one or more digital and/or analog signals. For example, and without limitation, signal transformation component 408 may be configured to perform one or more operations such as preprocessing, lexical analysis, parsing, semantic analysis, and the like thereof. In an embodiment, and without limitation, signal transformation component 408 may include one or more analog-to-digital convertors that transform a first signal of an analog signal to a second signal of a digital signal. For example, and without limitation, an analog-to-digital converter may convert an analog input signal to a 10-bit binary digital representation of that signal. In another embodiment, signal transformation component 408 may include transforming one or more low-level languages such as, but not limited to, machine languages and/or assembly languages. For example, and without limitation, signal transformation component 408 may include transforming a binary language signal to an assembly language signal. In an embodiment, and without limitation, signal transformation component 408 may include transforming one or more high-level languages and/or formal languages such as but not limited to alphabets, strings, and/or languages. For example, and without limitation, high-level languages may include one or more system languages, scripting languages, domain-specific languages, visual languages, esoteric languages, and the like thereof. As a further non-limiting example, high-level languages may include one or more algebraic formula languages, business data languages, string and list languages, object-oriented languages, and the like thereof.

Still referring to FIG. 4, signal transformation component 408 may be configured to optimize an intermediate representation 412. As used in this disclosure an “intermediate representation” is a data structure and/or code that represents the input signal. Signal transformation component 408 may optimize intermediate representation as a function of a data-flow analysis, dependence analysis, alias analysis, pointer analysis, escape analysis, and the like thereof. In an embodiment, and without limitation, signal transformation component 408 may optimize intermediate representation 412 as a function of one or more inline expansions, dead code eliminations, constant propagation, loop transformations, and/or automatic parallelization functions. In another embodiment, signal transformation component 408 may optimize intermediate representation as a function of a machine dependent optimization such as a peephole optimization, wherein a peephole optimization may rewrite short sequences of code into more efficient sequences of code. Signal transformation component 408 may optimize intermediate representation to generate an output language, wherein an “output language,” as used herein, is the native machine language of flight controller 404. For example, and without limitation, native machine language may include one or more binary and/or numerical languages.

In an embodiment, and without limitation, signal transformation component 408 may include transform one or more inputs and outputs as a function of an error correction code. An error correction code, also known as error correcting code (ECC), is an encoding of a message or lot of data using redundant information, permitting recovery of corrupted data. An ECC may include a block code, in which information is encoded on fixed-size packets and/or blocks of data elements such as symbols of predetermined size, bits, or the like. Reed-Solomon coding, in which message symbols within a symbol set having q symbols are encoded as coefficients of a polynomial of degree less than or equal to a natural number k, over a finite field F with q elements; strings so encoded have a minimum hamming distance of k+1, and permit correction of (q−k−1)/2 erroneous symbols. Block code may alternatively or additionally be implemented using Golay coding, also known as binary Golay coding, Bose-Chaudhuri, Hocquenghuem (BCH) coding, multidimensional parity-check coding, and/or Hamming codes. An ECC may alternatively or additionally be based on a convolutional code.

In an embodiment, and still referring to FIG. 4, flight controller 404 may include a reconfigurable hardware platform 416. A “reconfigurable hardware platform,” as used herein, is a component and/or unit of hardware that may be reprogrammed, such that, for instance, a data path between elements such as logic gates or other digital circuit elements may be modified to change an algorithm, state, logical sequence, or the like of the component and/or unit. This may be accomplished with such flexible high-speed computing fabrics as field-programmable gate arrays (FPGAs), which may include a grid of interconnected logic gates, connections between which may be severed and/or restored to program in modified logic. Reconfigurable hardware platform 416 may be reconfigured to enact any algorithm and/or algorithm selection process received from another computing device and/or created using machine-learning processes.

Still referring to FIG. 4, reconfigurable hardware platform 416 may include a logic component 420. As used in this disclosure a “logic component” is a component that executes instructions on output language. For example, and without limitation, logic component may perform basic arithmetic, logic, controlling, input/output operations, and the like thereof. Logic component 420 may include any suitable processor, such as without limitation a component incorporating logical circuitry for performing arithmetic and logical operations, such as an arithmetic and logic unit (ALU), which may be regulated with a state machine and directed by operational inputs from memory and/or sensors; logic component 420 may be organized according to Von Neumann and/or Harvard architecture as a non-limiting example. Logic component 420 may include, incorporate, and/or be incorporated in, without limitation, a microcontroller, microprocessor, digital signal processor (DSP), Field Programmable Gate Array (FPGA), Complex Programmable Logic Device (CPLD), Graphical Processing Unit (GPU), general purpose GPU, Tensor Processing Unit (TPU), analog or mixed signal processor, Trusted Platform Module (TPM), a floating point unit (FPU), and/or system on a chip (SoC). In an embodiment, logic component 420 may include one or more integrated circuit microprocessors, which may contain one or more central processing units, central processors, and/or main processors, on a single metal-oxide-semiconductor chip. Logic component 420 may be configured to execute a sequence of stored instructions to be performed on the output language and/or intermediate representation 412. Logic component 420 may be configured to fetch and/or retrieve the instruction from a memory cache, wherein a “memory cache,” as used in this disclosure, is a stored instruction set on flight controller 404. Logic component 420 may be configured to decode the instruction retrieved from the memory cache to opcodes and/or operands. Logic component 420 may be configured to execute the instruction on intermediate representation 412 and/or output language. For example, and without limitation, logic component 420 may be configured to execute an addition operation on intermediate representation 412 and/or output language.

In an embodiment, and without limitation, logic component 420 may be configured to calculate a flight element 424. As used in this disclosure a “flight element” is an element of datum denoting a relative status of aircraft. For example, and without limitation, flight element 424 may denote one or more torques, thrusts, airspeed velocities, forces, altitudes, groundspeed velocities, directions during flight, directions facing, forces, orientations, and the like thereof. For example, and without limitation, flight element 424 may denote that aircraft is cruising at an altitude and/or with a sufficient magnitude of forward thrust. As a further non-limiting example, flight status may denote that is building thrust and/or groundspeed velocity in preparation for a takeoff. As a further non-limiting example, flight element 424 may denote that aircraft is following a flight path accurately and/or sufficiently.

Still referring to FIG. 4, flight controller 404 may include a chipset component 428. As used in this disclosure a “chipset component” is a component that manages data flow. In an embodiment, and without limitation, chipset component 428 may include a northbridge data flow path, wherein the northbridge dataflow path may manage data flow from logic component 420 to a high-speed device and/or component, such as a RAM, graphics controller, and the like thereof. In another embodiment, and without limitation, chipset component 428 may include a southbridge data flow path, wherein the southbridge dataflow path may manage data flow from logic component 420 to lower-speed peripheral buses, such as a peripheral component interconnect (PCI), industry standard architecture (ICA), and the like thereof. In an embodiment, and without limitation, southbridge data flow path may include managing data flow between peripheral connections such as ethernet, USB, audio devices, and the like thereof. Additionally or alternatively, chipset component 428 may manage data flow between logic component 420, memory cache, and a flight component 432. As used in this disclosure a “flight component” is a portion of an aircraft that can be moved or adjusted to affect one or more flight elements. For example, flight component 432 may include a component used to affect the aircrafts' roll and pitch which may comprise one or more ailerons. As a further example, flight component 432 may include a rudder to control yaw of an aircraft. In an embodiment, chipset component 428 may be configured to communicate with a plurality of flight components as a function of flight element 424. For example, and without limitation, chipset component 428 may transmit to an aircraft rotor to reduce torque of a first lift propulsor and increase the forward thrust produced by a pusher component to perform a flight maneuver.

In an embodiment, and still referring to FIG. 4, flight controller 404 may be configured generate an autonomous function. As used in this disclosure an “autonomous function” is a mode and/or function of flight controller 404 that controls aircraft automatically. For example, and without limitation, autonomous function may perform one or more aircraft maneuvers, take offs, landings, altitude adjustments, flight leveling adjustments, turns, climbs, and/or descents. As a further non-limiting example, autonomous function may adjust one or more airspeed velocities, thrusts, torques, and/or groundspeed velocities. As a further non-limiting example, autonomous function may perform one or more flight path corrections and/or flight path modifications as a function of flight element 424. In an embodiment, autonomous function may include one or more modes of autonomy such as, but not limited to, autonomous mode, semi-autonomous mode, and/or non-autonomous mode. As used in this disclosure “autonomous mode” is a mode that automatically adjusts and/or controls aircraft and/or the maneuvers of aircraft in its entirety. For example, autonomous mode may denote that flight controller 404 will adjust the aircraft. As used in this disclosure a “semi-autonomous mode” is a mode that automatically adjusts and/or controls a portion and/or section of aircraft. For example, and without limitation, semi-autonomous mode may denote that a pilot will control the propulsors, wherein flight controller 404 will control the ailerons and/or rudders. As used in this disclosure “non-autonomous mode” is a mode that denotes a pilot will control aircraft and/or maneuvers of aircraft in its entirety.

In an embodiment, and still referring to FIG. 4, flight controller 404 may generate autonomous function as a function of an autonomous machine-learning model. As used in this disclosure an “autonomous machine-learning model” is a machine-learning model to produce an autonomous function output given flight element 424 and a pilot signal 436 as inputs; this is in contrast to a non-machine learning software program where the commands to be executed are determined in advance by a user and written in a programming language. As used in this disclosure a “pilot signal” is an element of datum representing one or more functions a pilot is controlling and/or adjusting. For example, pilot signal 436 may denote that a pilot is controlling and/or maneuvering ailerons, wherein the pilot is not in control of the rudders and/or propulsors. In an embodiment, pilot signal 436 may include an implicit signal and/or an explicit signal. For example, and without limitation, pilot signal 436 may include an explicit signal, wherein the pilot explicitly states there is a lack of control and/or desire for autonomous function. As a further non-limiting example, pilot signal 436 may include an explicit signal directing flight controller 404 to control and/or maintain a portion of aircraft, a portion of the flight plan, the entire aircraft, and/or the entire flight plan. As a further non-limiting example, pilot signal 436 may include an implicit signal, wherein flight controller 404 detects a lack of control such as by a malfunction, torque alteration, flight path deviation, and the like thereof. In an embodiment, and without limitation, pilot signal 436 may include one or more explicit signals to reduce torque, and/or one or more implicit signals that torque may be reduced due to reduction of airspeed velocity. In an embodiment, and without limitation, pilot signal 436 may include one or more local and/or global signals. For example, and without limitation, pilot signal 436 may include a local signal that is transmitted by a pilot and/or crew member. As a further non-limiting example, pilot signal 436 may include a global signal that is transmitted by air traffic control and/or one or more remote users that are in communication with the pilot of aircraft. In an embodiment, pilot signal 436 may be received as a function of a tri-state bus and/or multiplexor that denotes an explicit pilot signal should be transmitted prior to any implicit or global pilot signal.

Still referring to FIG. 4, autonomous machine-learning model may include one or more autonomous machine-learning processes such as supervised, unsupervised, or reinforcement machine-learning processes that flight controller 404 and/or a remote device may or may not use in the generation of autonomous function. As used in this disclosure “remote device” is an external device to flight controller 404. Additionally or alternatively, autonomous machine-learning model may include one or more autonomous machine-learning processes that a field-programmable gate array (FPGA) may or may not use in the generation of autonomous function. Autonomous machine-learning process may include, without limitation machine learning processes such as simple linear regression, multiple linear regression, polynomial regression, support vector regression, ridge regression, lasso regression, elasticnet regression, decision tree regression, random forest regression, logistic regression, logistic classification, K-nearest neighbors, support vector machines, kernel support vector machines, naïve bayes, decision tree classification, random forest classification, K-means clustering, hierarchical clustering, dimensionality reduction, principal component analysis, linear discriminant analysis, kernel principal component analysis, Q-learning, State Action Reward State Action (SARSA), Deep-Q network, Markov decision processes, Deep Deterministic Policy Gradient (DDPG), or the like thereof.

In an embodiment, and still referring to FIG. 4, autonomous machine learning model may be trained as a function of autonomous training data, wherein autonomous training data may correlate a flight element, pilot signal, and/or simulation data to an autonomous function. For example, and without limitation, a flight element of an airspeed velocity, a pilot signal of limited and/or no control of propulsors, and a simulation data of required airspeed velocity to reach the destination may result in an autonomous function that includes a semi-autonomous mode to increase thrust of the propulsors. Autonomous training data may be received as a function of user-entered valuations of flight elements, pilot signals, simulation data, and/or autonomous functions. Flight controller 404 may receive autonomous training data by receiving correlations of flight element, pilot signal, and/or simulation data to an autonomous function that were previously received and/or determined during a previous iteration of generation of autonomous function. Autonomous training data may be received by one or more remote devices and/or FPGAs that at least correlate a flight element, pilot signal, and/or simulation data to an autonomous function. Autonomous training data may be received in the form of one or more user-entered correlations of a flight element, pilot signal, and/or simulation data to an autonomous function.

Still referring to FIG. 4, flight controller 404 may receive autonomous machine-learning model from a remote device and/or FPGA that utilizes one or more autonomous machine learning processes, wherein a remote device and an FPGA is described above in detail. For example, and without limitation, a remote device may include a computing device, external device, processor, FPGA, microprocessor and the like thereof. Remote device and/or FPGA may perform the autonomous machine-learning process using autonomous training data to generate autonomous function and transmit the output to flight controller 404. Remote device and/or FPGA may transmit a signal, bit, datum, or parameter to flight controller 404 that at least relates to autonomous function. Additionally or alternatively, the remote device and/or FPGA may provide an updated machine-learning model. For example, and without limitation, an updated machine-learning model may be comprised of a firmware update, a software update, a autonomous machine-learning process correction, and the like thereof. As a non-limiting example a software update may incorporate a new simulation data that relates to a modified flight element. Additionally or alternatively, the updated machine learning model may be transmitted to the remote device and/or FPGA, wherein the remote device and/or FPGA may replace the autonomous machine-learning model with the updated machine-learning model and generate the autonomous function as a function of the flight element, pilot signal, and/or simulation data using the updated machine-learning model. The updated machine-learning model may be transmitted by the remote device and/or FPGA and received by flight controller 404 as a software update, firmware update, or corrected habit machine-learning model. For example, and without limitation autonomous machine learning model may utilize a neural net machine-learning process, wherein the updated machine-learning model may incorporate a gradient boosting machine-learning process.

Still referring to FIG. 4, flight controller 404 may include, be included in, and/or communicate with a mobile device such as a mobile telephone or smartphone. Further, flight controller may communicate with one or more additional devices as described below in further detail via a network interface device. The network interface device may be utilized for commutatively connecting a flight controller to one or more of a variety of networks, and one or more devices. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. The network may include any network topology and can may employ a wired and/or a wireless mode of communication.

In an embodiment, and still referring to FIG. 4, flight controller 404 may include, but is not limited to, for example, a cluster of flight controllers in a first location and a second flight controller or cluster of flight controllers in a second location. Flight controller 404 may include one or more flight controllers dedicated to data storage, security, distribution of traffic for load balancing, and the like. Flight controller 404 may be configured to distribute one or more computing tasks as described below across a plurality of flight controllers, which may operate in parallel, in series, redundantly, or in any other manner used for distribution of tasks or memory between computing devices. For example, and without limitation, flight controller 404 may implement a control algorithm to distribute and/or command the plurality of flight controllers. As used in this disclosure a “control algorithm” is a finite sequence of well-defined computer implementable instructions that may determine the flight component of the plurality of flight components to be adjusted. For example, and without limitation, control algorithm may include one or more algorithms that reduce and/or prevent aviation asymmetry. As a further non-limiting example, control algorithms may include one or more models generated as a function of a software including, but not limited to Simulink by MathWorks, Natick, Mass., USA. In an embodiment, and without limitation, control algorithm may be configured to generate an auto-code, wherein an “auto-code,” is used herein, is a code and/or algorithm that is generated as a function of the one or more models and/or software's. In another embodiment, control algorithm may be configured to produce a segmented control algorithm. As used in this disclosure a “segmented control algorithm” is control algorithm that has been separated and/or parsed into discrete sections. For example, and without limitation, segmented control algorithm may parse control algorithm into two or more segments, wherein each segment of control algorithm may be performed by one or more flight controllers operating on distinct flight components.

In an embodiment, and still referring to FIG. 4, control algorithm may be configured to determine a segmentation boundary as a function of segmented control algorithm. As used in this disclosure a “segmentation boundary” is a limit and/or delineation associated with the segments of the segmented control algorithm. For example, and without limitation, segmentation boundary may denote that a segment in the control algorithm has a first starting section and/or a first ending section. As a further non-limiting example, segmentation boundary may include one or more boundaries associated with an ability of flight component 432. In an embodiment, control algorithm may be configured to create an optimized signal communication as a function of segmentation boundary. For example, and without limitation, optimized signal communication may include identifying the discrete timing required to transmit and/or receive the one or more segmentation boundaries. In an embodiment, and without limitation, creating optimized signal communication further comprises separating a plurality of signal codes across the plurality of flight controllers. For example, and without limitation the plurality of flight controllers may include one or more formal networks, wherein formal networks transmit data along an authority chain and/or are limited to task-related communications. As a further non-limiting example, communication network may include informal networks, wherein informal networks transmit data in any direction. In an embodiment, and without limitation, the plurality of flight controllers may include a chain path, wherein a “chain path,” as used herein, is a linear communication path comprising a hierarchy that data may flow through. In an embodiment, and without limitation, the plurality of flight controllers may include an all-channel path, wherein an “all-channel path,” as used herein, is a communication path that is not restricted to a particular direction. For example, and without limitation, data may be transmitted upward, downward, laterally, and the like thereof. In an embodiment, and without limitation, the plurality of flight controllers may include one or more neural networks that assign a weighted value to a transmitted datum. For example, and without limitation, a weighted value may be assigned as a function of one or more signals denoting that a flight component is malfunctioning and/or in a failure state.

Still referring to FIG. 4, the plurality of flight controllers may include a master bus controller. As used in this disclosure a “master bus controller” is one or more devices and/or components that are connected to a bus to initiate a direct memory access transaction, wherein a bus is one or more terminals in a bus architecture. Master bus controller may communicate using synchronous and/or asynchronous bus control protocols. In an embodiment, master bus controller may include flight controller 404. In another embodiment, master bus controller may include one or more universal asynchronous receiver-transmitters (UART). For example, and without limitation, master bus controller may include one or more bus architectures that allow a bus to initiate a direct memory access transaction from one or more buses in the bus architectures. As a further non-limiting example, master bus controller may include one or more peripheral devices and/or components to communicate with another peripheral device and/or component and/or the master bus controller. In an embodiment, master bus controller may be configured to perform bus arbitration. As used in this disclosure “bus arbitration” is method and/or scheme to prevent multiple buses from attempting to communicate with and/or connect to master bus controller. For example and without limitation, bus arbitration may include one or more schemes such as a small computer interface system, wherein a small computer interface system is a set of standards for physical connecting and transferring data between peripheral devices and master bus controller by defining commands, protocols, electrical, optical, and/or logical interfaces. In an embodiment, master bus controller may receive intermediate representation 412 and/or output language from logic component 420, wherein output language may include one or more analog-to-digital conversions, low bit rate transmissions, message encryptions, digital signals, binary signals, logic signals, analog signals, and the like thereof described above in detail.

Still referring to FIG. 4, master bus controller may communicate with a slave bus. As used in this disclosure a “slave bus” is one or more peripheral devices and/or components that initiate a bus transfer. For example, and without limitation, slave bus may receive one or more controls and/or asymmetric communications from master bus controller, wherein slave bus transfers data stored to master bus controller. In an embodiment, and without limitation, slave bus may include one or more internal buses, such as but not limited to a/an internal data bus, memory bus, system bus, front-side bus, and the like thereof. In another embodiment, and without limitation, slave bus may include one or more external buses such as external flight controllers, external computers, remote devices, printers, aircraft computer systems, flight control systems, and the like thereof.

In an embodiment, and still referring to FIG. 4, control algorithm may optimize signal communication as a function of determining one or more discrete timings. For example, and without limitation master bus controller may synchronize timing of the segmented control algorithm by injecting high priority timing signals on a bus of the master bus control. As used in this disclosure a “high priority timing signal” is information denoting that the information is important. For example, and without limitation, high priority timing signal may denote that a section of control algorithm is of high priority and should be analyzed and/or transmitted prior to any other sections being analyzed and/or transmitted. In an embodiment, high priority timing signal may include one or more priority packets. As used in this disclosure a “priority packet” is a formatted unit of data that is communicated between the plurality of flight controllers. For example, and without limitation, priority packet may denote that a section of control algorithm should be used and/or is of greater priority than other sections.

Still referring to FIG. 4, flight controller 404 may also be implemented using a “shared nothing” architecture in which data is cached at the worker, in an embodiment, this may enable scalability of aircraft and/or computing device. Flight controller 404 may include a distributer flight controller. As used in this disclosure a “distributer flight controller” is a component that adjusts and/or controls a plurality of flight components as a function of a plurality of flight controllers. For example, distributer flight controller may include a flight controller that communicates with a plurality of additional flight controllers and/or clusters of flight controllers. In an embodiment, distributed flight control may include one or more neural networks. For example, neural network also known as an artificial neural network, is a network of “nodes,” or data structures having one or more inputs, one or more outputs, and a function determining outputs based on inputs. Such nodes may be organized in a network, such as without limitation a convolutional neural network, including an input layer of nodes, one or more intermediate layers, and an output layer of nodes. Connections between nodes may be created via the process of “training” the network, in which elements from a training dataset are applied to the input nodes, a suitable training algorithm (such as Levenberg-Marquardt, conjugate gradient, simulated annealing, or other algorithms) is then used to adjust the connections and weights between nodes in adjacent layers of the neural network to produce the desired values at the output nodes. This process is sometimes referred to as deep learning.

Still referring to FIG. 4, a node may include, without limitation a plurality of inputs xᵢ that may receive numerical values from inputs to a neural network containing the node and/or from other nodes. Node may perform a weighted sum of inputs using weights wᵢ that are multiplied by respective inputs xᵢ. Additionally or alternatively, a bias b may be added to the weighted sum of the inputs such that an offset is added to each unit in the neural network layer that is independent of the input to the layer. The weighted sum may then be input into a function φ, which may generate one or more outputs y. Weight wᵢ applied to an input xᵢ may indicate whether the input is “excitatory,” indicating that it has strong influence on the one or more outputs y, for instance by the corresponding weight having a large numerical value, and/or a “inhibitory,” indicating it has a weak effect influence on the one more inputs y, for instance by the corresponding weight having a small numerical value. The values of weights wᵢ may be determined by training a neural network using training data, which may be performed using any suitable process as described above. In an embodiment, and without limitation, a neural network may receive semantic units as inputs and output vectors representing such semantic units according to weights wᵢ that are derived using machine-learning processes as described in this disclosure.

Still referring to FIG. 4, flight controller may include a sub-controller 440. As used in this disclosure a “sub-controller” is a controller and/or component that is part of a distributed controller as described above; for instance, flight controller 404 may be and/or include a distributed flight controller made up of one or more sub-controllers. For example, and without limitation, sub-controller 440 may include any controllers and/or components thereof that are similar to distributed flight controller and/or flight controller as described above. Sub-controller 440 may include any component of any flight controller as described above. Sub-controller 440 may be implemented in any manner suitable for implementation of a flight controller as described above. As a further non-limiting example, sub-controller 440 may include one or more processors, logic components and/or computing devices capable of receiving, processing, and/or transmitting data across the distributed flight controller as described above. As a further non-limiting example, sub-controller 440 may include a controller that receives a signal from a first flight controller and/or first distributed flight controller component and transmits the signal to a plurality of additional sub-controllers and/or flight components.

Still referring to FIG. 4, flight controller may include a co-controller 444. As used in this disclosure a “co-controller” is a controller and/or component that joins flight controller 404 as components and/or nodes of a distributer flight controller as described above. For example, and without limitation, co-controller 444 may include one or more controllers and/or components that are similar to flight controller 404. As a further non-limiting example, co-controller 444 may include any controller and/or component that joins flight controller 404 to distributer flight controller. As a further non-limiting example, co-controller 444 may include one or more processors, logic components and/or computing devices capable of receiving, processing, and/or transmitting data to and/or from flight controller 404 to distributed flight control system. Co-controller 444 may include any component of any flight controller as described above. Co-controller 444 may be implemented in any manner suitable for implementation of a flight controller as described above.

In an embodiment, and with continued reference to FIG. 4, flight controller 404 may be designed and/or configured to perform any method, method step, or sequence of method steps in any embodiment described in this disclosure, in any order and with any degree of repetition. For instance, flight controller 404 may be configured to perform a single step or sequence repeatedly until a desired or commanded outcome is achieved; repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. Flight controller may perform any step or sequence of steps as described in this disclosure in parallel, such as simultaneously and/or substantially simultaneously performing a step two or more times using two or more parallel threads, processor cores, or the like; division of tasks between parallel threads and/or processes may be performed according to any protocol suitable for division of tasks between iterations. Persons skilled in the art, upon reviewing the entirety of this disclosure, will be aware of various ways in which steps, sequences of steps, processing tasks, and/or data may be subdivided, shared, or otherwise dealt with using iteration, recursion, and/or parallel processing.

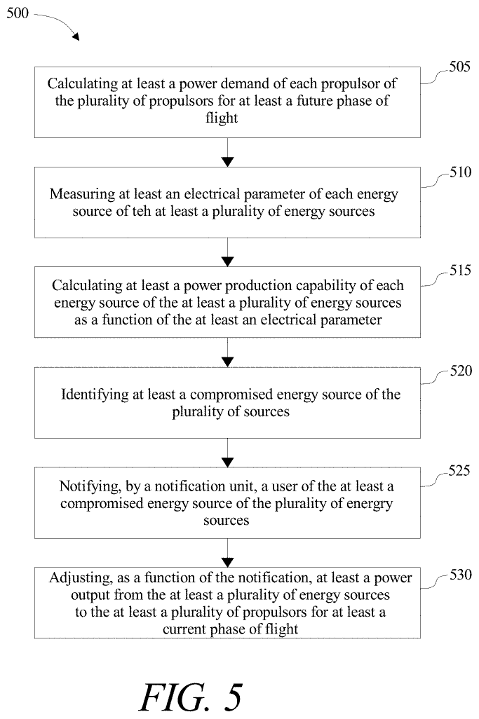

Referring now to FIG. 5, an embodiment of a method 500 of in-flight operational assessment is illustrated. At step 505, a power demand of each propulsor 108 of a plurality of propulsors is calculated for at least a future phase of flight. Power demand may be calculated using one or more of various factors, including without limitation manufacture supplied data for propulsor, engine and/or motor. In an embodiment, factors used to calculate the power demand calculation may use weight and/or payload of aircraft 304 in addition to manufacturing data. Power demand, as a non-limiting example, may be a function of such elements as a required speed of the propulsor for any phase of flight, weight or payload, altitude, temperature, weather, environmental conditions, and/or size, type and or shape of a propeller blade, rotor blade, and/or other propulsor blade. Power demand may alternatively or additionally, without limitation, be a function of a type, size and age of one or more motors driving or incorporated in plurality of propulsors. As a non-limiting example, power demand may be calculated for a portion of the flight and/or the entire phase of a flight or flight plan. As another example and without limitation, power demand of at least a propulsor 108 of a plurality of propulsors, at a point of time or for the remaining time of the particular phase of flight may be calculated. As another example and without limitation, power demand may be calculated for each individual propulsor during a phase of flight or for the entire flight plan. As another example and without limitation, power demand may be calculated for the plurality of propulsors and divided by the number of propulsors for a phase of flight of the entire flight plan. As another example and without limitation, power demand for an individual propulsor or a plurality of propulsors may be done at any part of the flight or flight plan and may be done multiple times during flight.

Continuing to refer to FIG. 5, a projected power demand for performing at a particular phase of flight may be stored in memory accessible to controller 112. For instance, controller 112 may store in its memory projected energy needed to perform a scheduled landing according to a landing protocol called for in flight plan, a likely energy cost of traveling a particular distance while cruising, and the like. Stored energy costs may include, without limitation, one or more dependencies on conditions of flight; for instance, energy needed to travel a certain distance through the air may depend on speed and direction of wind, air density, degree of turbulence, exterior temperature, or the like. In an embodiment and without limitation, calculating further includes determining a current state of electronic aircraft 304 with respect to flight plan. Calculating, as an example and without limitation, may also be dependent on the weight of energy source 104 and surrounding supporting functions. As a further non-limiting example, calculating may also depend on the weight of the load being transported. Determination of current state may include, without limitation, identifying a current location of electronic aircraft 304. As another non-limiting example, current location of electronic aircraft 304 may be determined using elapsed time of flight, geographical position as calculated by GPS or similar systems, information about current position as received from other parties such as air traffic controllers, and/or optical, radar, or Lidar data identifying landmarks or other geographic features outside electronic aircraft. Calculation may further include, without limitation, identifying a remaining portion of flight plan as a function of current state.

With continued reference to FIG. 5, calculating the at least a projected power demand need may include receiving at least a datum from a remote device 340 and calculating the at least a projected energy need and/or power demand as a function of the at least a datum. At least a datum may include, without limitation, weather information, such as barometric pressure, upcoming storm systems, direction and velocity of wind, and the like; such data may be received from a remote device 340 operated by a weather service, or from any other remote device 340 having access to weather forecast or current state information. As a non-limiting example, controller 112 may determine that electronic aircraft 304 is flying into a headwind of a given velocity and may increase an estimate of power the aircraft will consume while cruising against the headwind; estimates may alternatively be revised downward for a tailwind. As another example, controller 112 may increase energy consumption estimates as a function of a predicted storm; where aircraft must be routed around the storm, for instance, controller 112 may predict increased energy consumption to perform the lengthier route, while if aircraft is going to proceed through the storm, projected power consumption may be increased based on anticipated increases in turbulence, headwind, or the like. At least a datum may include, without limitation, information conveyed from a remote device 340 operated by air traffic control. Information may include, for instance and without limitation, instruct aircraft to reroute to a different landing site, or to land according to a different protocol.

Continuing to reference FIG. 5, at step 510, controller 112 measures at least an electrical parameter of each energy source of plurality of energy sources. At least an electrical parameter may be measured, for instance, using any means or method as described above, such as using at least a sensor 116 and/or via an electrical or other connection between controller 112 and at least an energy source 104, of a plurality of energy sources. In an embodiment, measuring the at least an electrical parameter further includes, without limitation, measuring a voltage. For example and without limitation, voltage of a battery cell, a plurality of battery cells, modules or plurality of modules may be measured. Voltage under load may be alternatively or additionally measured. For example and without limitation, measuring at least an electrical parameter may include measuring a current; a current of a battery cell, a plurality of battery cells, modules or plurality of modules may be measured. Measuring at least an electrical parameter may include, without limitation, inferring or calculating an electrical parameter based on sensed electrical parameters, for example by using Ohm's law to calculate resistance and/or impedance from detected voltage and current levels. At least an electrical parameter may include, as a non-limiting example, signal properties such as frequency, wavelength, or amplitude of one or more components of a voltage or current signal. Persons skilled in the art, upon reviewing the entirety of this disclosure, will be aware of various electrical parameters, and techniques for measuring such parameters, consistent with this disclosure.

Still viewing FIG. 5, measuring at least an electrical parameter may include detecting a change in the at least an electrical parameter. In an embodiment, the change in voltage as a function of time may be measured. In an embodiment, a change in current as a function of time may be measured. As an example and without limitation, detecting a change in the at least an electrical parameter may be accomplished by repeatedly measuring or sampling data detected by at least a sensor 116. As another non-limiting example, detecting a change in the at least an electrical parameter may be accomplished by controller 112 and using the repeated samples or measurement to calculate changes or rates of change. As a further example and without limitation, detecting a change in the at least an electrical parameter may be accomplished by a curve, graph, or continuum of measured values may be matched to mathematical functions using, such as linear approximation, splining, Fourier series calculations, or the like. In an embodiment, detecting a change in at least an electrical parameter may include, without limitation, detecting a change in a first electrical parameter of the at least an electrical parameter, detecting a change in a second electrical parameter of the at least an electrical parameter, and calculating a dependency of the second electrical parameter on the first electrical parameter. In an embodiment, detecting a change in at least an electrical parameter may further include, without limitation, calculating a change in voltage as a function of time. As an example and without limitation, calculating a change in voltage as a function of time may include sampling voltage repeatedly or continuously over a time period, and the rate of change over time may be observed. As another non-limiting example, detecting a change in at least an electrical parameter may further include, without limitation, detecting current as a function of voltage. As an example and without limitation, detecting current as a function of voltage may include instantaneous or average voltage may be divided by current according to Ohm's law to determine resistance, while instantaneous or average impedance may similarly be calculated using formulas relating voltage, current, or other parameters to impedance. As another non-limiting example, detection of at least an electrical parameter may be performed by digital sampling. As an example and without limitation, digital sampling may include at least an electrical parameter that is directly measured may be sampled, such as, at a rate expressed in frequency of sample per second, such as without limitation a 10 Hz sample rate. Directly measured or sampled electrical parameter may be subjected to one or more signal processing actions, including scaling, low-pass filtering, high-pass filtering, band-pass filtering, band-stop filtering, noise filtering, or the like.

Referring again to FIG. 5, in an embodiment, state of voltage (SOV) may be used instead of or in addition to state of charge to determine a current state and power-production capability of at least an energy source 104. State of voltage may be determined based on open-circuit voltage. As an example and without limitation, open circuit voltage may be estimated using voltage across terminals, such as by subtracting a product of current and resistance, as detected and/or calculated using measured or sampled values, to determine open-circuit voltage. As a non-limiting example, instantaneous current and voltage may be sampled and/or measured to determine Delta V and Delta I, representing instantaneous changes to voltage and current, which may be used in turn to estimate instantaneous resistance. As a further example and without limitation, low-pass filtering may be used to determine instantaneous resistance more closely resembling a steady-state output resistance of at least an energy source 104 than from transient effects, either for discharge or recharge resistance. As another non-limiting example, open-circuit voltage may, in turn be used to estimate depth of discharge (DOD) and/or SOC, such as by reference to a data sheet graph or other mapping relating open circuit voltage to DOD and/or SOC. Remaining charge in at least an energy source 104 may alternatively or additionally be estimated by one or more other methods including without limitation current integrator estimate of charge remaining.

Still referring to FIG. 5, detecting change in first electrical parameter may include inducing the change in the electrical parameter. For instance, and without limitation, first electrical parameter may include output current of at least an energy source; controller 112 may induce an increased output current by increasing an energy demand of one or more components or elements electrically connected to at least an energy source 104, of a plurality of energy sources, and observe output voltage of at least an energy source 104, of a plurality of energy sources, that results from the modified current. Similarly, controller may increase or decrease resistance seen by at least an energy source 104, of a plurality of energy sources, for instance by switching one or more resisters in parallel or in series with propulsor 108, of a plurality of propulsors, by modifying a resistance level of a transistor, such as a power FET controlling supply to a propulsor 108, of a plurality of propulsors, or the like; output voltage, output current, or other electrical parameters' changes may then be measured.

In an embodiment, and still referring to FIG. 5, inducing change in first electrical parameter may further include modifying electrical power being supplied to at least a propulsor of the electronic aircraft from an energy source of the at least an energy source. In an embodiment, the controller 112 may reduce power to a propulsor from at least an energy source 104 to reduce speed or altitude. Alternatively or additionally, controller 112 may increase power to a propulsor from at least an energy source 104, of a plurality of energy sources, increasing speed or altitude. In an embodiment, when power to propulsor is increased or decreased relatively briefly, or to a limited extent, there may be a negligible change in speed or altitude as a result of the change. Alternatively or additionally, increases or decreases in power to a propulsor may be balanced by counteracting increases or decreases in power. For instance, controller 112 may apply more torque, causing the provision of more power, to one propulsor of multiple propulsors while applying less torque, and thus providing less power to another propulsor, such that net increased or decreased power from all propulsors is unchanged; this may be done alternately between sides so a course of electronic aircraft 300 is unaltered. Alternatively or additionally, two or more energy sources of at least an energy source 104 may be connected to a motor that has dual (or multiple) windings, each winding going to a different separate energy source. Power to one set of windings may be increased while power to other windings is deceased, such that at least one source of the at least an energy source 104, of a plurality of energy sources, has a net increase or decrease in power output while a change in propulsive power from the propulsor is negligible or nonexistent. Multiple energy sources of at least an energy source 104, of a plurality of energy sources, may have power increased or decreased, permitting measurement of resulting changes in at least an electrical parameter for each of multiple energy sources.

In an embodiment, and still viewing FIG. 5, induced change in first parameter may have one or more signal properties. For instance, and without limitation, induced change may be an impulse function or the like. Alternatively, induced change may be a pulse function representing a step from a first value to a second value followed at some interval to a step back to the first value. Interval may be, for example and without limitation, a period of second, milliseconds, or the like. In an embodiment, parameter values measured for a pulse response may reflect steady-state values more accurately than parameter values measured for an impulse response or vice-versa. For instance, and without limitation, an output impedance of at least an energy source 104, of a plurality of energy sources, measured in response to an impulse may differ from an output impedance of the at least an energy source 104 as measured in response to a pulse; as an example, capacitance and/or inductance may cause higher impedances in response to impulse signals and/or high-frequency signals than in response to steadier pulse function signals, the latter of which may have more characteristics in common with power demands of a flight maneuver such as a landing sequence. Although the above description has involved observation of at least an electrical parameter based on changes to other electrical parameters, in an embodiment, a change in at least an electrical parameter resulting from a change to another parameter may also be observed. For instance, and without limitation, a change in temperature may induce a change in voltage or current as a function of resistance within at least an energy source 104, of a plurality of energy sources. This may also be observed and used as part of a calculation as set forth in further detail below.

Still viewing FIG. 5, at step 515, controller 112 calculates at least a power-production capability of each energy source 104 of the plurality of energy sources as a function of the at least an electrical parameter. As used herein, a power-production capability is a capability to deliver power and/or energy to a load or component powered by at least an electrical energy source. A power-production capability may include power delivery capability. As an example and without limitation, power delivery capability may include peak power-production capability and average power-production capability. As an example and without limitation, power delivery capability may include a duration of time during which a given power level, such as peak and/or average power-production capability. As an example and without limitation, power delivery capability may include a time at which a given power level may be delivered, where the time is provided in terms of a measure of time in seconds or other units from a given moment, a measure of time in seconds or other units from a given point in a flight plan, or as a given point in a flight plan, such as a time when power may be provided may be rendered as a time at which an aircraft arrives at a particular stage in a flight plan. As a non-limiting example, power delivery capability may indicate whether peak power may be provided at or during a landing stage of flight. Power-production capability may include energy delivery capability, such as without limitation a total amount of remaining energy deliverable by a given electrical energy source. As a further non-limiting example, energy delivery capability further includes one or more factors such as time, temperature, or rate that may affect the total amount of energy available, such as circumstances that increase output impedance and/or resistance of at least an electrical energy source. Energy delivery capabilities help determine in practical terms how much energy may actually be delivered to components, may be a part of energy delivery capability.

With continued reference to FIG. 5, calculation of power-production capability may be performed by any suitable method, including without limitation using one or more models of at least an energy source of plurality of energy sources 104 to predict one or more circuit parameters of electric power output. As an example and without limitation, one or more circuit parameters of electric power output may include power, current, voltage, resistance or any other measure of a parameter of an electric circuit which impacts or influences power, for instance as described above. As a further example, one or more models may include, without limitation, a lookup or reference table providing the one or more circuit parameters based on conditions of at least an energy source and/or of a circuit containing the at least an energy source. As an example, conditions may include, without limitation, a state of charge of the at least an energy source, a temperature of the at least an energy source, a resistance of a load connected to the at least an energy source, a current, voltage, or power demand of a circuit or load connected to the at least an energy source, or the like. As an example and without limitation, one or more models may include one or more equations, reference, graphs, or maps relating the one or more circuit parameters to one or more conditions as described above. As an example and without limitation, one or more models may be created using data from a data sheet or other data provided by a manufacturer, data received from one or more sensors during operation of system 100, simulation generated using a simulation program that models circuit behaviors, analysis of analogous circuits, any combination thereof, or any other predictive and/or sensor-based methods for determining relationships between one or more circuit parameters and one or more conditions. Power capability and/or power-production capability of at least an energy source of plurality of energy sources 104 may decline after each flight cycle, portion of flight or maneuver, producing a new set of data or reference tables to calculate parameters.

Still referring to FIG. 5, SOV and/or open circuit voltage of at least an energy source 104 and/or one or more cells or components thereof may be used to determine power-production capability in an embodiment. Discharging a battery to the minimum allowed cell potential may give maximum discharge power. Maximum discharge power may be a function of a cell's open circuit potential and series resistance, as determined for instance using the following equation:

$$Pcell \cdot max discharge = ( Voc - Vcell \cdot min ) * \frac{Vcell \cdot min}{Cell \cdot resistance \cdot discharge}$$

where Voc is open circuit voltage, Vcell.min is the minimum allowed open circuit potential, and cell.resistance.discharge is a cell's discharge resistance, which may be calculated in an embodiment as described above. One or more additional calculations may be used to aid in determination of likely future behavior of at least an electrical energy source. For instance, a derivative of open circuit voltage with respect to SOC may be calculated and/or plotted. Open circuit voltage and the derivative of open circuit voltage with respect to SOC, as plotted against SOC, is illustrated in a figure below. Alternatively or additionally, a derivative of resistance with respect to SOC may be tracked.

Referring again to FIG. 5, at least an energy source of a plurality of energy sources 104 may include a plurality of energy sources connected in series. For instance, at least an energy source may include a set of batteries and/or cells connected in series to achieve a particular voltage, or the like. Determining power-production capability of at least an energy source may include determining a plurality of component energy capabilities representing the energy capabilities of each energy source of the plurality of energy sources, identifying a lowest component energy capability of the plurality of component energy capabilities, and determining the delivery capability of the at least an energy source as a function of the lowest component energy capability. For instance, and without limitation, one cell or battery connected in series with at least another cell or battery may have a lower SOC, or otherwise be able to produce less total energy and/or power than the at least another battery or cell; as a result, at least an energy source of plurality of energy sources 104 overall may be limited primarily by the cell or battery with lower SOC, making the effective power-production capability overall dependent on the power-production capability of the cell or battery with the lowest SOC.

Still referring to FIG. 5, in an embodiment, an SOC of at least an energy source of plurality of energy sources 104 may be calculated with datum obtained from sensor 116, or a plurality of sensors during any portion of the flight. Datum may be received at remote device 354 or may be calculated using estimation methods used to estimate the SOC. Datum may include, without limitation, voltage, current, resistance, impedance, and/or temperature of at least an energy source 104, of a plurality of energy sources. These estimations may include, without limitation, coulomb counting, open circuit voltage, impedance, or other models the like. For example and without limitation, estimations may also use lookup tables or equivalent data structures. As a non-limiting example data structures may be obtained from technical specifications, such as datasheets, describing the energy source behavior under, without limitation, load and environmental conditions. Alternatively or additionally, one or more mathematical relations may be used to determine current SOC while in flight. Persons skilled in the art will be aware, upon reviewing the entirety of this disclosure, will be aware of various combinations of methods used to determine SOC.

Continuing to refer to FIG. 5, at step 520, controller 112 identifies at least one compromised energy source that does not have adequate power-production capability for at least a phase of flight. In an embodiment, adequate power capability may be measured for power capability without use of safety reserve power such that integrity of safety reserve may be maintained for emergent conditions. Alternatively or additionally, determination of power delivery may be performed with safety reserve power included. Determination of power capability may be performed to account for a full range of potential problems and solutions. Controller 112 may identify at least a compromised energy source as a function of at least an electrical parameter. Controller 112 may determine that at least an electrical parameter does not meet the threshold for the at least a power demand. An electrical parameter that does not meet the threshold for the at least a power demand may be stored in memory of controller 112. The threshold for the at least a power demand is the threshold as described above in reference to FIG. 1. Controller 112 may take static or dynamic power output measurements as described above to determine if there is at least an energy source that may not have adequate power for an associated propulsor for the particular phase of flight. The measurements may be a fixed value or a range. Controller 112 may use the measurements of the energy source and compare it with the other energy sources to determine that it is out of a specific range. Range value may be, without limitation, a measurement of self-discharge, SOC, capability, voltage, resistance and current. Controller may use a pre-determined value that shows the measurement as a function of time, voltage, current, SOC, capability or resistance. There may be one or more energy sources of a plurality of energy sources 104 which do not have the required power output to continue with the phase of flight in addition to remaining phases of flight. The identification of the compromised energy source or energy sources may be done automatically by a computer or manually by a person or persons. In an embodiment, controller 112 may create a first number representing power-production capability of an energy source of plurality of energy sources 104 and a second number representing at least a projected power demand of electronic aircraft 300 and/or of one or more propulsors, and compare the two numbers; controller 112 may maintain a buffer number by which power-production capability must exceed at least a projected power need, where buffer number may include, or be based on, safety reserve as described above. Controller 112 may determine that power-production capability is sufficient for at least projected energy need if the two numbers are equal; controller 112 may determine that power-production capability is sufficient for at least a projected energy need if power-production capability exceeds at least a projected energy need by buffer number. Controller 112 may perform this calculation using lookup tables or mathematical relations as described above; for instance, controller 112 may retrieve from a lookup table a potential level necessary to drive a propulsor at a given velocity. Controller 112 may perform a calculation based on the demands described above which determines a rate of power consumption based on the demand by the propulsors at a given time in flight. This power consumption rate may be used to determine if the power demand of propulsors needed to arrive at the originally selected location using the originally selected landing method is possible given the current energy source capability. Persons skilled in the art, upon reviewing the entirety of this disclosure, will be aware of various alternative means for determining a potential demand of a propulsor as described herein. First flight plan may include, without limitation, the geospatial location of the landing site, the calculated distance to the landing site, the time required to reach the landing site, the landing methods.

Still referring to FIG. 5, at step 525, notification unit 120 notifies the user of the at least a compromised energy source 104 of the plurality of energy sources. Notification to the user by the notification unit 120 may be in any form of communication as described herein such as through visual cues, heads-up displays, visors, goggles, projections, holograms, videos, pictures, graphical representations of data such as voltage over time, audio cues such as dings, chimes, bells, robotic voice recordings, prerecorded audio warning messages, tones, alarms, or the like. Notification to the user by notification unit 120 may include haptic feedback such as vibrations, jostling of controls, resistance to control inputs, or the like, in non-limiting embodiments. Notification to the user by notification unit 120 may be configured to prompt the user for an interaction such as an approval, denial, adjustment, or other manipulation of a command, such as a command to adjust one or more electrical parameters or outputs of other components within system 100 such as propulsor 108 or energy source 104 to name a few consistent with the entirety of this disclosure.

Still referring to FIG. 5, at step 530, controller 112 adjusts, as a function of the notification of the user by notification unit 120, power output from the at least a plurality of energy sources 104 to the at least a plurality of propulsors for a current phase of flight to compensate for at least a compromised energy source. Current phase of flight may be a phase of flight in which aircraft is currently engaged; for instance, where aircraft is taking off, current phase of flight may be takeoff and future phases of flight may include cruising and/or landing, while if aircraft is cruising, current phase of flight may be cruising, and future phases of flight may include landing. Controller 112 may adjust power output from the at least a plurality of energy sources as a function of a prompted interaction with the user and notification unit 120. Controller 112 may adjust power output from the at least a plurality of energy sources in response to an interaction with notification unit 120 by the user such as a voice, haptic, or gesture interaction. It should be noted by one of ordinary skill in the art that system 100 may be configured to adjust power output autonomously and without initiation or intervention from the user regardless of notification unit 120 notifying the user. That is to say that in an exemplary embodiment, notification unit 120 displays the power levels or compromised energy source to the user, and controller 112 then adjusts power output in response to the detection of the compromised energy source 104. In another exemplary embodiment, controller 112 may be configured to adjust power output from energy source 104 after notification unit 120 displays and prompts the user for an interaction and receives the interaction with notification unit 120. Controller 112 may, for example and without limitation, direct one of more propulsors to operate at a reduced rate dependent on the power-production capability of the identified energy source that is out of a specific range described above. Controller 112 may, for example and without limitation, calculate the balance of thrust to ensure that the aircraft avoids severe pitch and yaw. Controller 112 may, as another example and without limitation, continually measure thrust and balance during the particular phase of flight with reduced power levels. As a further non-limiting example, controller 112 may recalculate power needs according to step 505 at any time during the phase of flight to reassess the power demand of at least a propulsor and the power-production capability of energy source. As a further non-limiting example, controller 112 may reassess the flight plan and modify any phase of the flight plan in order to match the power-production capability of an energy source of plurality of energy sources 104. As a further non-limiting example, controller 112 may increase power output from a plurality of energy sources 104 to a plurality of propulsors to keep the aircraft in flight and in the air or determine by balancing calculations, which propulsors, of a plurality of propulsors needs to be increased while others are decreased. As another example and without limitation, controller 112 may determine an alternate landing zone in route to the final destination of electric aircraft 300. An alternate landing zone may include a location with a system and/or combination of systems capable of recharging each energy source of the plurality of energy sources.

Still referring to FIG. 5, in an embodiment, sensor feedback using any sensor as described above may replace or supplement calculation of potential and/or power consumption requirements. Controller 112 may record sensor feedback indicating angular velocity of and/or torque exerted by a motor in one or more instances, along with corresponding electrical parameters of the circuit driving motor such as voltage, current, power consumed, or the like, and storing values so derived. As a further example and without limitation, controller 112 may look up such stored values to determine potential and/or power consumption at a given desired angular speed or torque for a propulsor. As another non-limiting example, controller 112 may perform interpolation or regression to predict likely potential and/or power consumption at an angular speed and/or torque not specifically recorded. Persons skilled in the art, upon reviewing the entirety of this disclosure, will be aware of various ways in which sensor feedback and calculation may be combined consistently with this disclosure to determine potential and/or power consumption needs of a propulsor and/or plurality of propulsors.

Still referring to FIG. 5, controller 112 will adjust the power output to a plurality of propulsors by determining a minimum power demand of propulsor 108, of a plurality of propulsors, needed for a future phase of flight using the speed, distance, altitude and the like. The calculation may use manufacturing data or data collected by a plurality of sensors during flight. Controller 112 will calculate an aggregate power-production capability of the plurality of energy sources as a function of the power-production capability of each energy source of the plurality of energy sources. Using that measurement, controller 112 will determine if the aggregate power-production capability is sufficient based on the minimum power demand. Controller 112 will determine if the minimum power demand exceeds the aggregate power demand, and if it does, will recalculate at least a future phase of flight to ensure that there is adequate power for the remaining flight plan. In an embodiment controller 112 may recalculate a flight maneuver based on the power demand of that maneuver and the remaining power capability of the at least an energy source 104, of a plurality of energy sources. An example is that controller 112 may direct a runway landing vs hovering if the hovering maneuver takes additional power. Controller 112 may direct the aircraft to a new location which has less external and environmental forces which cause an increase in the consumption of power. Using the minimum power demand for a particular phase of flight, controller 112 may determine the total power demand for the plurality of propulsors by using the power demand of an individual propulsor and multiplying that by the number of propulsors. In an embodiment, controller 112 will determine if there is enough power in the plurality of energy sources to power the phase of flight and the rest of the flight plan. If there is enough power, controller 112 will continue to communicate the original flight plan. If there in not adequate power, controller 112 will reduce the power demand by allocating the remain power output of the plurality of energy sources to one or more motors connected to a propulsor of a plurality of propulsors by communications to the motor 304 supplying power to the plurality of propulsors. Controller 112 may perform a thrust and/or balance operation to determine if the balance of the aircraft, as a result of the reduced power levels, is operating in a safe range.

Continuing to refer to FIG. 5, in an embodiment, if there is not adequate power, even at a reduced power level, to supply power to the plurality of propulsors, controller 112 may direct a calculation of a different flight plan or maneuver which has reduced power demands. The flight plan may be a portion of the entire flight plan or the entire flight plan. Controller 112 may direct a different landing protocol and/or location, which consumes less power. Controller 112 may direct a different flying maneuver which consumes less power. Controller 112 may reduce power to non-critical functions of the aircraft in order to allocate the minimum power required for each of the propulsors to maintain a flight plan. Controller 112 may calculate which of the other aircraft critical functions can operate with a reduction in power while maintain the safety of the aircraft.

With continued reference to FIG. 5, in an embodiment, controller 112 may direct the aircraft to change to a flight trajectory which requires reduced power demands. As an example and without limitation, controller 112 may generate and/or store a number of predetermined flight trajectories. As another non-limiting example, controller 112 may calculate and/or store a range of suitable flight trajectories ranked by power demand for a particular flight phase or for the entire flight phase, or both. As a further example and without limitation, controller 112 may select a top ranked flight trajectory for phase of flight or the entire flight. As a further example and without limitation, controller 112 may select a different flight trajectory for each flight phase. As a further example and without limitation, controller 112 may select more than one flight trajectory and communicate to a remote device or person for consideration. For example and without limitation, one or more flight trajectories may include a combination of geospatial coordinates, a series of waypoints, altitude assignments, and/or time assignments. As another non-limiting example, one or more flight trajectories may include, without limitation, a straight flight course occurring at the same altitude, a spiral flight course which includes turns, a combination of both or a reduction in altitude. In an embodiment, controller 112 may reduce one or more propulsors to operate at a reduced power level that make the aircraft unbalanced and operate in a corkscrew pattern to cruise and or land safely.

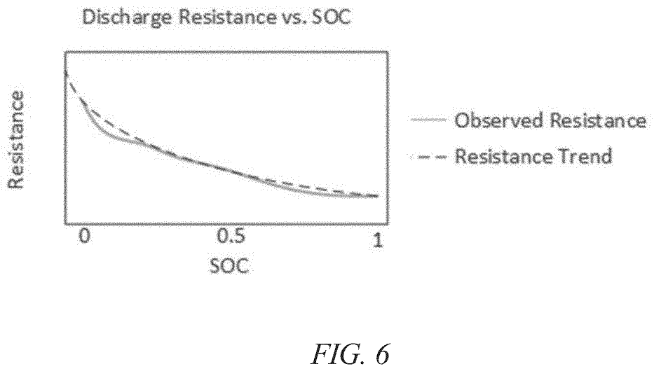

Referring now to FIG. 6, a graph illustrating discharge voltage with respect to SOC, as plotted against SOC is illustrated. As used herein, a remaining flight time and/or power output plurality of energy sources 104, or individual energy sources. Energy sources 104 capable of delivering may be calculated using a SOC vs time curve. Calculation may include, as a non-limiting example, plotting points on SOC vs. time curve to determine a point along the curve at least an energy source of plurality of energy sources 104, a component cell, and/or other portion thereof has arrived. Determining a point along the curve may enable controller 112 to predict future potential power output by reference to remainder of curve. For a particular energy source, the design may dictate safe operation SOC conditions as indicated in figures below. As an example and without limitation, a safety reserve, such as a gas tank reserve, may also be designated based on the design characteristics and manufacturing data; such as operating range may by enforced by the controller 112, energy source 104 of a plurality of energy sources may only operate in the designated operating range, and a safety reserve may only be used in cases where a critical functions demand power in order to ensure a safe flight.

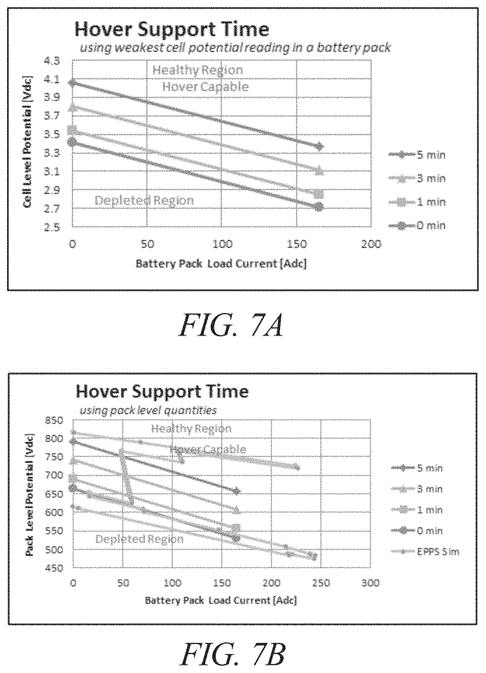

Referring now to FIG. 7A-B, power-production capability may be calculated or provided with respect to one or more flight maneuvers. As a non-limiting example, power-production capability may be expressed in terms of hover support time. Hover support time as described herein may be defined as a period of time for which at least an energy source is capable of outputting sufficient power to permit electric aircraft to hover. FIG. 7A illustrates how hover support time may be mapped against observed terminal potential and current for a plurality of measured potentials. As an example and without limitation, a potential ranging from 5.1 V to 3.4 V over a current range of 0 to 160 Amps may correspond to a hover support time of 6 minutes, while a voltage range over the same current range of 3.8 to 3.1 V may correspond to an over time of 3 minutes. FIG. 7A represents actual behavior of a battery and/or cell may be compared to or plotted over a gradient. FIG. 7B, for instance, illustrates actual behavior of a battery and/or cell may be compared to or plotted over a gradient, where an additional line on top indicates a hover time somewhat in excess of 6 minutes as compared to the gradient, in this non-limiting example. Alternatively or additionally, ability to land and/or perform another flight maneuver may similarly be estimated.

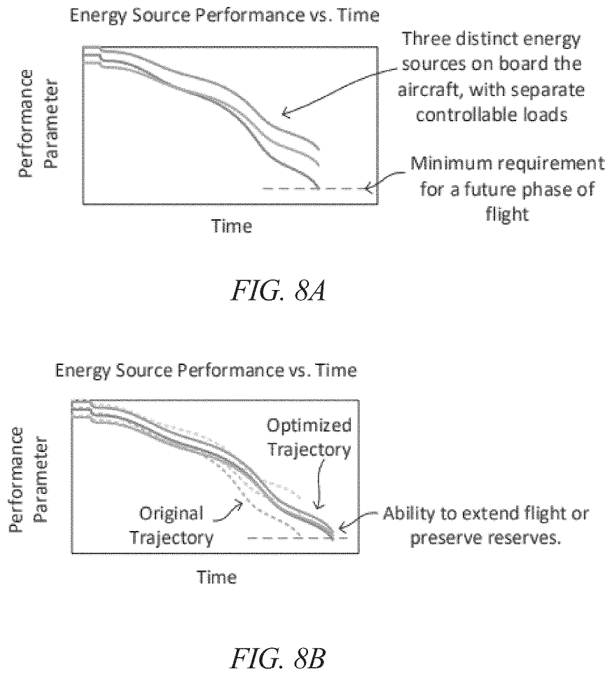

Referring now to FIG. 8A-B, the graph illustrate an energy source performance of an embodiment of an energy source as a function of time. In an embodiment, determining power-production capability may further include determining an energy source performance parameter, such as, without limitation, state of charge (SOC) of at least an energy source of plurality of energy sources 104. Determining power-production capability may include, without limitation, comparing at least an electrical parameter to a curve representing a projected evolution over time of at least an energy source 104, of a plurality of energy sources. In an embodiment, information plotting the energy source performance parameter against time may be used to determine power and energy outputs of the energy source and may represent available battery capability. In an embodiment, at least an energy source of plurality of energy sources 104 may consist of a plurality of cells, including without limitation battery cells. Energy source performance may be impacted by a chemistry type and/or footprint of one or more cells which may affect charge and/or discharge rates, and/or the operational range over time. As an example and without limitation, Energy source performance may also be impacted by any component of system 100 or an aircraft containing system 100, such as wiring, conduit, housing or any other hardware which may cause resistance during use. Cycle life of at least an energy source 104, of a plurality of energy sources, may also be affected by a number of charge and discharge cycles completed in operation. As an example and without limitation, capability of at least an energy source 104 to store energy may decrease after several iterations of a charge/discharge cycle over its lifetime and the graph in FIG. 8A-B may change over time. As a further example and without limitation, capacity of an energy source of plurality of energy sources 104, when including a plurality of cells connected in series in a module, may decrease due to differences in discharge rates of individual cells in the series connection. For example, discharge rates may be related to or caused by variables such as, without limitation, temperature, initial tolerances, material impurities, porosity, electrolyte density, surface contamination, and/or age. A low-capability battery cell may discharge more rapidly than other cells in a module. As a non-limiting example, a damaged battery may have lower capability and will become discharged more rapidly than a healthy battery.

Still referring to FIG. 8A-B, calculation of power-production capability may further include modifying a curve as a function of the at least an electrical parameter. As an example and without limitation, determining may include modifying an energy source performance curve as a function of the at least an electrical parameter. As a further example, as at least an energy source 104, of a plurality of energy sources, is being used the available capability output may be reduced. The available capability output may be, without limitation, measured as a change in voltage over time. In an embodiment, projected data curves for the power output delivery based on the calculations may be recalculated. As described above, the energy source performance parameter of at least an energy source of plurality of energy sources 104 may degrade after each flight and charge and discharge cycle. The new curves generated will be used to determine future power output delivery capabilities. Any or all steps of the method may be repeated in any order. For example and without limitation, the energy source performance of at least an energy source of plurality of energy sources 104 may be calculated more than one time during a flight in order to accurately ensure at least an energy source of plurality of energy sources 104 has the power output capability for the chosen landing method and location, as described in further detail above. In an embodiment and without limitation, controller 112 may compare one or more sampled values of at least an electrical parameter to curve, wherein values tend to be more than a threshold amount off of the projected curve. For example and without limitation, controller 112 may replace that curve with another one, such as replacing the curve with one representing an energy source performance curve for an energy source of plurality of energy sources 104 that is more aged, and thus has a higher output resistance, for an energy source having a higher temperature resulting in a higher output resistance, or the like.

In an embodiment, the above-described elements may alleviate problems resulting from systems wherein at least an energy source may not have the required power capability for a particular phase of flight. An in-flight optimization of the remaining in-flight power output capability will ensure safe operation for any phase of the flight including taxi, take off, cruise and landing modes. There are other methods which can optimize the power management of energy sources such as connected all energy sources to all propulsors, but this adds weight to the aircraft that is not desirable. Above-described embodiments enable the optimization of power sources in a lightweight and robust configuration compatible with safe and high-performance flight.

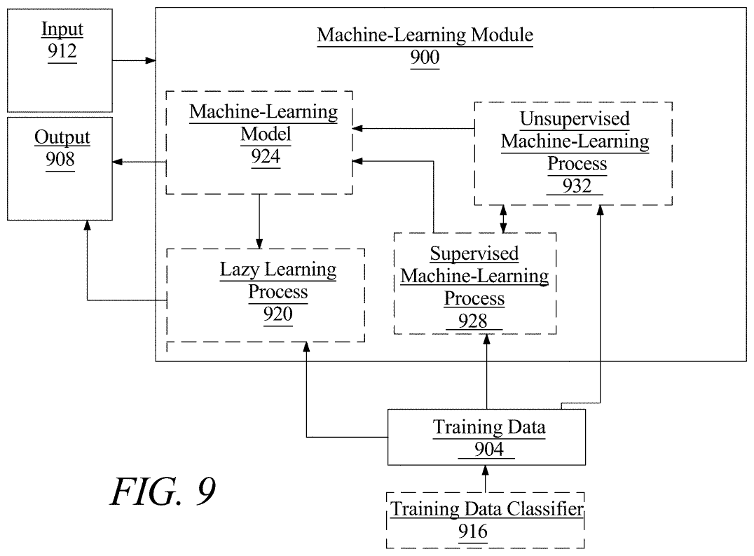

Referring now to FIG. 9, an exemplary embodiment of a machine-learning module 900 that may perform one or more machine-learning processes as described in this disclosure is illustrated. Machine-learning module may perform determinations, classification, and/or analysis steps, methods, processes, or the like as described in this disclosure using machine learning processes. A “machine learning process,” as used in this disclosure, is a process that automatedly uses training data 904 to generate an algorithm that will be performed by a computing device/module to produce outputs 908 given data provided as inputs 912; this is in contrast to a non-machine learning software program where the commands to be executed are determined in advance by a user and written in a programming language.

Still referring to FIG. 9, “training data,” as used herein, is data containing correlations that a machine-learning process may use to model relationships between two or more categories of data elements. For instance, and without limitation, training data 904 may include a plurality of data entries, each entry representing a set of data elements that were recorded, received, and/or generated together; data elements may be correlated by shared existence in a given data entry, by proximity in a given data entry, or the like. Multiple data entries in training data 904 may evince one or more trends in correlations between categories of data elements; for instance, and without limitation, a higher value of a first data element belonging to a first category of data element may tend to correlate to a higher value of a second data element belonging to a second category of data element, indicating a possible proportional or other mathematical relationship linking values belonging to the two categories. Multiple categories of data elements may be related in training data 904 according to various correlations; correlations may indicate causative and/or predictive links between categories of data elements, which may be modeled as relationships such as mathematical relationships by machine-learning processes as described in further detail below. Training data 904 may be formatted and/or organized by categories of data elements, for instance by associating data elements with one or more descriptors corresponding to categories of data elements. As a non-limiting example, training data 904 may include data entered in standardized forms by persons or processes, such that entry of a given data element in a given field in a form may be mapped to one or more descriptors of categories. Elements in training data 904 may be linked to descriptors of categories by tags, tokens, or other data elements; for instance, and without limitation, training data 904 may be provided in fixed-length formats, formats linking positions of data to categories such as comma-separated value (CSV) formats and/or self-describing formats such as extensible markup language (XML), JavaScript Object Notation (JSON), or the like, enabling processes or devices to detect categories of data.

Alternatively or additionally, and continuing to refer to FIG. 9, training data 904 may include one or more elements that are not categorized; that is, training data 904 may not be formatted or contain descriptors for some elements of data. Machine-learning algorithms and/or other processes may sort training data 904 according to one or more categorizations using, for instance, natural language processing algorithms, tokenization, detection of correlated values in raw data and the like; categories may be generated using correlation and/or other processing algorithms. As a non-limiting example, in a corpus of text, phrases making up a number “n” of compound words, such as nouns modified by other nouns, may be identified according to a statistically significant prevalence of n-grams containing such words in a particular order; such an n-gram may be categorized as an element of language such as a “word” to be tracked similarly to single words, generating a new category as a result of statistical analysis. Similarly, in a data entry including some textual data, a person's name may be identified by reference to a list, dictionary, or other compendium of terms, permitting ad-hoc categorization by machine-learning algorithms, and/or automated association of data in the data entry with descriptors or into a given format. The ability to categorize data entries automatedly may enable the same training data 904 to be made applicable for two or more distinct machine-learning algorithms as described in further detail below. Training data 904 used by machine-learning module 900 may correlate any input data as described in this disclosure to any output data as described in this disclosure. As a non-limiting illustrative example flight elements and/or pilot signals may be inputs, wherein an output may be an autonomous function.

Further referring to FIG. 9, training data may be filtered, sorted, and/or selected using one or more supervised and/or unsupervised machine-learning processes and/or models as described in further detail below; such models may include without limitation a training data classifier 916. Training data classifier 916 may include a “classifier,” which as used in this disclosure is a machine-learning model as defined below, such as a mathematical model, neural net, or program generated by a machine learning algorithm known as a “classification algorithm,” as described in further detail below, that sorts inputs into categories or bins of data, outputting the categories or bins of data and/or labels associated therewith. A classifier may be configured to output at least a datum that labels or otherwise identifies a set of data that are clustered together, found to be close under a distance metric as described below, or the like. Machine-learning module 900 may generate a classifier using a classification algorithm, defined as a processes whereby a computing device and/or any module and/or component operating thereon derives a classifier from training data 904. Classification may be performed using, without limitation, linear classifiers such as without limitation logistic regression and/or naive Bayes classifiers, nearest neighbor classifiers such as k-nearest neighbors classifiers, support vector machines, least squares support vector machines, fisher's linear discriminant, quadratic classifiers, decision trees, boosted trees, random forest classifiers, learning vector quantization, and/or neural network-based classifiers. As a non-limiting example, training data classifier 416 may classify elements of training data to sub-categories of flight elements such as torques, forces, thrusts, directions, and the like thereof.

Still referring to FIG. 9, machine-learning module 900 may be configured to perform a lazy-learning process 920 and/or protocol, which may alternatively be referred to as a “lazy loading” or “call-when-needed” process and/or protocol, may be a process whereby machine learning is conducted upon receipt of an input to be converted to an output, by combining the input and training set to derive the algorithm to be used to produce the output on demand. For instance, an initial set of simulations may be performed to cover an initial heuristic and/or “first guess” at an output and/or relationship. As a non-limiting example, an initial heuristic may include a ranking of associations between inputs and elements of training data 904. Heuristic may include selecting some number of highest-ranking associations and/or training data 904 elements. Lazy learning may implement any suitable lazy learning algorithm, including without limitation a K-nearest neighbors algorithm, a lazy naïve Bayes algorithm, or the like; persons skilled in the art, upon reviewing the entirety of this disclosure, will be aware of various lazy-learning algorithms that may be applied to generate outputs as described in this disclosure, including without limitation lazy learning applications of machine-learning algorithms as described in further detail below.

Alternatively or additionally, and with continued reference to FIG. 9, machine-learning processes as described in this disclosure may be used to generate machine-learning models 924. A “machine-learning model,” as used in this disclosure, is a mathematical and/or algorithmic representation of a relationship between inputs and outputs, as generated using any machine-learning process including without limitation any process as described above, and stored in memory; an input is submitted to a machine-learning model 924 once created, which generates an output based on the relationship that was derived. For instance, and without limitation, a linear regression model, generated using a linear regression algorithm, may compute a linear combination of input data using coefficients derived during machine-learning processes to calculate an output datum. As a further non-limiting example, a machine-learning model 924 may be generated by creating an artificial neural network, such as a convolutional neural network comprising an input layer of nodes, one or more intermediate layers, and an output layer of nodes. Connections between nodes may be created via the process of “training” the network, in which elements from a training data 904 set are applied to the input nodes, a suitable training algorithm (such as Levenberg-Marquardt, conjugate gradient, simulated annealing, or other algorithms) is then used to adjust the connections and weights between nodes in adjacent layers of the neural network to produce the desired values at the output nodes. This process is sometimes referred to as deep learning.

Still referring to FIG. 9, machine-learning algorithms may include at least a supervised machine-learning process 928. At least a supervised machine-learning process 928, as defined herein, include algorithms that receive a training set relating a number of inputs to a number of outputs, and seek to find one or more mathematical relations relating inputs to outputs, where each of the one or more mathematical relations is optimal according to some criterion specified to the algorithm using some scoring function. For instance, a supervised learning algorithm may include flight elements and/or pilot signals as described above as inputs, autonomous functions as outputs, and a scoring function representing a desired form of relationship to be detected between inputs and outputs; scoring function may, for instance, seek to maximize the probability that a given input and/or combination of elements inputs is associated with a given output to minimize the probability that a given input is not associated with a given output. Scoring function may be expressed as a risk function representing an “expected loss” of an algorithm relating inputs to outputs, where loss is computed as an error function representing a degree to which a prediction generated by the relation is incorrect when compared to a given input-output pair provided in training data 904. Persons skilled in the art, upon reviewing the entirety of this disclosure, will be aware of various possible variations of at least a supervised machine-learning process 928 that may be used to determine relation between inputs and outputs. Supervised machine-learning processes may include classification algorithms as defined above.

Further referring to FIG. 9, machine learning processes may include at least an unsupervised machine-learning processes 932. An unsupervised machine-learning process, as used herein, is a process that derives inferences in datasets without regard to labels; as a result, an unsupervised machine-learning process may be free to discover any structure, relationship, and/or correlation provided in the data. Unsupervised processes may not require a response variable; unsupervised processes may be used to find interesting patterns and/or inferences between variables, to determine a degree of correlation between two or more variables, or the like.

Still referring to FIG. 9, machine-learning module 900 may be designed and configured to create a machine-learning model 924 using techniques for development of linear regression models. Linear regression models may include ordinary least squares regression, which aims to minimize the square of the difference between predicted outcomes and actual outcomes according to an appropriate norm for measuring such a difference (e.g. a vector-space distance norm); coefficients of the resulting linear equation may be modified to improve minimization. Linear regression models may include ridge regression methods, where the function to be minimized includes the least-squares function plus term multiplying the square of each coefficient by a scalar amount to penalize large coefficients. Linear regression models may include least absolute shrinkage and selection operator (LASSO) models, in which ridge regression is combined with multiplying the least-squares term by a factor of 1 divided by double the number of samples. Linear regression models may include a multi-task lasso model wherein the norm applied in the least-squares term of the lasso model is the Frobenius norm amounting to the square root of the sum of squares of all terms. Linear regression models may include the elastic net model, a multi-task elastic net model, a least angle regression model, a LARS lasso model, an orthogonal matching pursuit model, a Bayesian regression model, a logistic regression model, a stochastic gradient descent model, a perceptron model, a passive aggressive algorithm, a robustness regression model, a Huber regression model, or any other suitable model that may occur to persons skilled in the art upon reviewing the entirety of this disclosure. Linear regression models may be generalized in an embodiment to polynomial regression models, whereby a polynomial equation (e.g. a quadratic, cubic or higher-order equation) providing a best predicted output/actual output fit is sought; similar methods to those described above may be applied to minimize error functions, as will be apparent to persons skilled in the art upon reviewing the entirety of this disclosure.

Continuing to refer to FIG. 9, machine-learning algorithms may include, without limitation, linear discriminant analysis. Machine-learning algorithm may include quadratic discriminate analysis. Machine-learning algorithms may include kernel ridge regression. Machine-learning algorithms may include support vector machines, including without limitation support vector classification-based regression processes. Machine-learning algorithms may include stochastic gradient descent algorithms, including classification and regression algorithms based on stochastic gradient descent. Machine-learning algorithms may include nearest neighbors algorithms. Machine-learning algorithms may include Gaussian processes such as Gaussian Process Regression. Machine-learning algorithms may include cross-decomposition algorithms, including partial least squares and/or canonical correlation analysis. Machine-learning algorithms may include naïve Bayes methods. Machine-learning algorithms may include algorithms based on decision trees, such as decision tree classification or regression algorithms. Machine-learning algorithms may include ensemble methods such as bagging meta-estimator, forest of randomized tress, AdaBoost, gradient tree boosting, and/or voting classifier methods. Machine-learning algorithms may include neural net algorithms, including convolutional neural net processes.

It is to be noted that any one or more of the aspects and embodiments described herein may be conveniently implemented using one or more machines (e.g., one or more computing devices that are utilized as a user computing device for an electronic document, one or more server devices, such as a document server, etc.) programmed according to the teachings of the present specification, as will be apparent to those of ordinary skill in the computer art. Appropriate software coding can readily be prepared by skilled programmers based on the teachings of the present disclosure, as will be apparent to those of ordinary skill in the software art. Aspects and implementations discussed above employing software and/or software modules may also include appropriate hardware for assisting in the implementation of the machine executable instructions of the software and/or software module.

Such software may be a computer program product that employs a machine-readable storage medium. A machine-readable storage medium may be any medium that is capable of storing and/or encoding a sequence of instructions for execution by a machine (e.g., a computing device) and that causes the machine to perform any one of the methodologies and/or embodiments described herein. Examples of a machine-readable storage medium include, but are not limited to, a magnetic disk, an optical disc (e.g., CD, CD-R, DVD, DVD-R, etc.), a magneto-optical disk, a read-only memory “ROM” device, a random access memory “RAM” device, a magnetic card, an optical card, a solid-state memory device, an EPROM, an EEPROM, and any combinations thereof. A machine-readable medium, as used herein, is intended to include a single medium as well as a collection of physically separate media, such as, for example, a collection of compact discs or one or more hard disk drives in combination with a computer memory. As used herein, a machine-readable storage medium does not include transitory forms of signal transmission.

Such software may also include information (e.g., data) carried as a data signal on a data carrier, such as a carrier wave. For example, machine-executable information may be included as a data-carrying signal embodied in a data carrier in which the signal encodes a sequence of instruction, or portion thereof, for execution by a machine (e.g., a computing device) and any related information (e.g., data structures and data) that causes the machine to perform any one of the methodologies and/or embodiments described herein.

Examples of a computing device include, but are not limited to, an electronic book reading device, a computer workstation, a terminal computer, a server computer, a handheld device (e.g., a tablet computer, a smartphone, etc.), a web appliance, a network router, a network switch, a network bridge, any machine capable of executing a sequence of instructions that specify an action to be taken by that machine, and any combinations thereof. In one example, a computing device may include and/or be included in a kiosk.

FIG. 10 shows a diagrammatic representation of one embodiment of a computing device in the form of a computer system 1000 within which a set of instructions for causing a control system, such as the vehicle system of FIG. 10, to perform any one or more of the aspects and/or methodologies of the present disclosure may be executed. It is also contemplated that multiple computing devices may be utilized to implement a specially configured set of instructions for causing one or more of the devices to perform any one or more of the aspects and/or methodologies of the present disclosure. Computer system 1000 includes a processor 1004 and a memory 1008 that communicate with each other, and with other components, via a bus 1012. Bus 1012 may include any of several types of bus structures including, but not limited to, a memory bus, a memory controller, a peripheral bus, a local bus, and any combinations thereof, using any of a variety of bus architectures.

Memory 1008 may include various components (e.g., machine-readable media) including, but not limited to, a random-access memory component, a read only component, and any combinations thereof. In one example, a basic input/output system 1016 (BIOS), including basic routines that help to transfer information between elements within computer system 1000, such as during start-up, may be stored in memory 1008. Memory 1008 may also include (e.g., stored on one or more machine-readable media) instructions (e.g., software) 1020 embodying any one or more of the aspects and/or methodologies of the present disclosure. In another example, memory 1008 may further include any number of program modules including, but not limited to, an operating system, one or more application programs, other program modules, program data, and any combinations thereof.

Computer system 1000 may also include a storage device 1024. Examples of a storage device (e.g., storage device 1024) include, but are not limited to, a hard disk drive, a magnetic disk drive, an optical disc drive in combination with an optical medium, a solid-state memory device, and any combinations thereof. Storage device 1024 may be connected to bus 1012 by an appropriate interface (not shown). Example interfaces include, but are not limited to, SCSI, advanced technology attachment (ATA), serial ATA, universal serial bus (USB), IEEE 1394 (FIREWIRE), and any combinations thereof. In one example, storage device 1024 (or one or more components thereof) may be removably interfaced with computer system 1000 (e.g., via an external port connector (not shown)). Particularly, storage device 1024 and an associated machine-readable medium 1028 may provide nonvolatile and/or volatile storage of machine-readable instructions, data structures, program modules, and/or other data for computer system 1000. In one example, software 1020 may reside, completely or partially, within machine-readable medium 1028. In another example, controller 112 may reside, completely or partially, within processor 1004.

Computer system 1000 may also include an input device 1032. In one example, a user of computer system 1000 may enter commands and/or other information into computer system 1000 via input device 1032. Examples of an input device 1032 include, but are not limited to, an alpha-numeric input device (e.g., a keyboard), a pointing device, a joystick, a gamepad, an audio input device (e.g., a microphone, a voice response system, etc.), a cursor control device (e.g., a mouse), a touchpad, an optical scanner, a video capture device (e.g., a still camera, a video camera), a touchscreen, and any combinations thereof. Input device 1032 may be interfaced to bus 1012 via any of a variety of interfaces (not shown) including, but not limited to, a serial interface, a parallel interface, a game port, a USB interface, a FIREWIRE interface, a direct interface to bus 1012, and any combinations thereof. Input device 1032 may include a touch screen interface that may be a part of or separate from display 1036, discussed further below. Input device 1032 may be utilized as a user selection device for selecting one or more graphical representations in a graphical interface as described above.

A user may also input commands and/or other information to computer system 1000 via storage device 1024 (e.g., a removable disk drive, a flash drive, etc.) and/or network interface device 1040. A network interface device, such as network interface device 1040, may be utilized for connecting computer system 1000 to one or more of a variety of networks, such as network 1044, and one or more remote devices 1048 connected thereto. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network, such as network 1044, may employ a wired and/or a wireless mode of communication. In general, any network topology may be used. Information (e.g., data, software 1020, etc.) may be communicated to and/or from computer system 1000 via network interface device 1040.

Computer system 1000 may further include a video display adapter 1052 for communicating a displayable image to a display device, such as display device 1036. Examples of a display device include, but are not limited to, a liquid crystal display (LCD), a cathode ray tube (CRT), a plasma display, a light emitting diode (LED) display, and any combinations thereof. Display adapter 1052 and display device 1036 may be utilized in combination with processor 1004 to provide graphical representations of aspects of the present disclosure. In addition to a display device, computer system 1000 may include one or more other peripheral output devices including, but not limited to, an audio speaker, a printer, and any combinations thereof. Such peripheral output devices may be connected to bus 1012 via a peripheral interface 1056. Examples of a peripheral interface include, but are not limited to, a serial port, a USB connection, a FIREWIRE connection, a parallel connection, and any combinations thereof.

The foregoing has been a detailed description of illustrative embodiments of the invention. Various modifications and additions can be made without departing from the spirit and scope of this invention. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present invention. Additionally, although particular methods herein may be illustrated and/or described as being performed in a specific order, the ordering is highly variable within ordinary skill to achieve methods, systems, and software according to the present disclosure. Accordingly, this description is meant to be taken only by way of example, and not to otherwise limit the scope of this invention.

embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. A system for altering propulsor output when powering an electronic aircraft, the system comprising:
a plurality of energy sources of an electronic aircraft;
a plurality of propulsors of an electronic aircraft, wherein the plurality of propulsors are powered by the plurality of energy sources;
at least a controller in communication with the at least a plurality of energy sources and the at least a plurality of propulsors, wherein the controller is configured to calculate at least a power demand of each propulsor of the plurality of propulsors for at least a future phase of flight;
at least a sensor in communication with the at least a controller; and
a notification unit in communication with the at least a controller.

2. The system of claim 1, wherein the electronic aircraft further comprises a vertical takeoff and landing aircraft.

3. The system of claim 1, wherein the at least an energy source further comprises at least a cell.

4. The system of claim 3, wherein the at least a cell further comprises:
a chemoelectrical cells;
a battery cell;
a photoelectric cell; and
a fuel cell.

5. The system of claim 1, wherein the at least a controller is further configured to:
measure at least an electrical parameter of each energy source of the plurality of energy sources; and
calculate at least a power-production capability of each energy source of the plurality of energy sources as a function of the at least an electrical parameter.

6. The system of claim 1, wherein the at least a controller is further configured to:
identify at least a compromised energy source of the plurality of energy sources, wherein the at least a compromised energy source does not meet at least a threshold; and
adjust at least a power output from the at least a plurality of energy sources to the at least a plurality of propulsors for at least a current phase of flight as a function of the at least a power-production capability of each energy source of the plurality of energy sources and the at least a power demand of each propulsor of the plurality of propulsors.

7. The system of claim 1, wherein the at least a sensor further comprises an environmental sensor.

8. The system of claim 1, wherein the at least a sensor further comprises a geospatial sensor.

9. A method of altering propulsor output when powering an electronic aircraft by at least a controller, the method comprising:
calculating, as a function of the at least a plurality of energy sources and at least a plurality of propulsors, at least a power demand of each propulsor of the plurality of propulsors for at least a future phase of flight, wherein each propulsor of the plurality of propulsors is powered by at least an energy source of a plurality of energy sources;
measuring at least an electrical parameter of each energy source of the at least a plurality of energy sources;
calculating at least a power-production capability of each energy source of the at least a plurality of energy sources as a function of the at least an electrical parameter;
identifying at least a compromised energy source of the plurality of sources;
notifying, by a notification unit, a user of the at least a compromised energy source of the plurality of sources; and
adjusting, as a function of the notification to the user by the notification unit, at least a power output from the at least a plurality of energy sources to the at least a plurality of propulsors for at least a current phase of flight as a function of the at least a power-production capability of each energy source of the plurality of energy sources and the at least a power demand of each propulsor of the plurality of propulsors.

10. The method of claim 9, wherein the electronic aircraft further comprises a vertical takeoff and landing vehicle.

11. The method of claim 9, wherein measuring the at least an electrical parameter further comprises detecting a change in the at least an electrical parameter.

12. The method of claim 9, wherein at least an energy source of the plurality of energy sources further comprises at least a cell.

13. The method of claim 12, wherein the at least a cell further comprises:
a chemoelectrical cell;
a battery cell;
a photoelectric cell; and
a fuel cell.

14. The method of claim 9, wherein identifying the at least a compromised energy source is performed as a function of the at least an electrical parameter.

15. The method of claim 9, wherein identifying at least a compromised energy source further comprises determining the at least a compromised energy source does not meet the threshold for the at least a power demand.

16. The method of claim 9, wherein adjusting at least a power output from the at least a plurality of energy sources to the at least a plurality of propulsors further comprises:
determining a minimum power demand needed for the at least a future phase of flight;
calculating an aggregate power-production capability of the plurality of energy sources as a function of the power-production capability of each energy source of the plurality of energy sources; and
determining whether the aggregate power-production capability is sufficient for the minimum power demand.

17. The method of claim 9, wherein adjusting at least a power output from the at least a plurality of energy sources to the at least a plurality of propulsors further comprises:
determining that the minimum power demand exceeds the aggregate power demand; and
recalculating the at least a future phase of flight, wherein recalculating ensures there is adequate power for the at least a future phase of flight.

18. The method of claim 10, wherein adjusting at least a power output from the at least a plurality of energy sources to the at least a plurality of propulsors further comprises further comprises reducing the at least a power output to at least an aircraft component.

19. The method of claim 18, wherein reducing the at least a power output to at least an aircraft component further comprises identifying at least an aircraft component capable of function at a reduced power level.

20. The method of claim 1, wherein adjusting the at least a power output from the at least a plurality of energy sources to the at least a plurality of propulsors further comprises:
reducing the at least a power output to the at least a compromised energy source; and
increasing the at least a power output to at least an energy source of the plurality of energy sources not including the at least a compromised energy source.
